(19) United States
(12) Patent Application Publication
(10) Pub. No.: US 2025/0107066 A1
(43) Pub. Date: Mar. 27, 2025

(54) SEMICONDUCTOR MEMORY DEVICE

(71) Applicant: Samsung Electronics Co., Ltd., Suwon-si (KR)

(72) Inventors: Bo Won Yoo, Suwon-si (KR); Jin Woo Han, Suwon-si (KR); Seok Han Park, Suwon-si (KR); Sung-Min Park, Suwon-si (KR); Gyu Hwan Oh, Suwon-si (KR)

(21) Appl. No.: 18/643,311

(22) Filed: Apr. 23, 2024

(30) Foreign Application Priority Data
Sep. 25, 2023 (KR) 10-2023-0128569

(51) Int. Cl. H10B 12/00; G11C 5/06

(52) U.S. Cl. CPC H10B 12/315; G11C 5/063; H10B 12/482; H10B 12/485; H10B 12/488

(57) ABSTRACT

A semiconductor memory device includes a cell region element separation film that is on a substrate and includes first and second cell region side walls; an active pattern that is on the substrate; a word line that is on the first side wall of the active pattern; a back gate electrode that is on the second side wall of the active pattern; a bit line that is electrically connected to the first side of the active pattern; and a data storage pattern that is electrically connected to the second side of the active pattern, where the word line includes an electrode part and a plug connecting part, and where the plug connecting part of the word line includes a first connecting extending part and a second connecting extending part.

### CROSS-REFERENCE TO RELATED APPLICATION

This application claims priority from Korean Patent Application No. 10-2023-0128569 filed on Sep. 25, 2023 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor memory device, and more specifically, to a semiconductor memory device including a vertical channel transistor (VCT).

### BACKGROUND

It may be desirable to increase the degree of integration of the semiconductor memory device to satisfy excellent performance and low price desired by consumers. In the case of the semiconductor memory device, because the degree of integration is a factor in determining the price of a product, an increased degree of integration is particularly desired.

In the case of a two-dimensional or planar semiconductor memory device, the degree of integration is mainly determined by an area occupied by unit memory cells, and is therefore greatly affected by the level of fine pattern forming technology. However, since expensive apparatuses are required to miniaturize the pattern, the degree of integration of the two-dimensional semiconductor memory device is increasing, but is still limited. Accordingly, semiconductor memory devices that include vertical channel transistors whose channels extend in a vertical direction are proposed.

### SUMMARY

Aspects of the present disclosure provide a semiconductor memory device having improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising a cell region element separation film that is on a substrate and includes a first cell region side wall and a second cell region side wall, where the first cell region side wall extends in a first direction, and where the second cell region side wall extends in a second direction; an active pattern that is on the substrate and includes a first side wall and a second side wall that are opposite to each other in the first direction and a first side and a second side that are opposite to each other in a third direction, where the first side of the active pattern faces the substrate; a word line that is on the first side wall of the active pattern and extends in the second direction; a back gate electrode that is on the second side wall of the active pattern and extends in the second direction; a bit line that is electrically connected to the first side of the active pattern and extends in the first direction; and a data storage pattern that is electrically connected to the second side of the active pattern, where the word line includes an electrode part that extends in the second direction and along the back gate electrode, where the word line includes a plug connecting part that extends beyond the back gate electrode in the second direction, where the plug connecting part of the word line includes a first connecting extending part that extends in the first direction and a second connecting extending part that extends in the second direction, and where the second connecting extending part of the word line is between the electrode part of the word line and the first connecting extending part of the word line.

According to an aspect of the present disclosure, there is provided a semiconductor memory device comprising a cell region element separation film that is on a substrate and includes a first cell region side wall and a second cell region side wall, where the first cell region side wall extends in a first direction, and where the second cell region side wall extends in a second direction; back gate electrodes that are on the substrate and extend in the second direction; a first word line and a second word line that are between the back gate electrodes and extend in the second direction; active patterns that are between the second word line and the first word line and that are spaced apart in the second direction; bit lines that are between the substrate and the first and second word lines and that extend in the first direction; and a data storage pattern that is on and electrically connected to the active patterns, where each of the first word line and the second word line includes an electrode part that extends in the second direction and along the back gate electrodes and a plug connecting part that extends from the back gate electrodes and in the second direction, where each of the plug connecting part of the first word line and the plug connecting part of the second word line includes a first connecting extending part that extends in the first direction and a second connecting extending part that extends in the second direction, where the second connecting extending part of the first word line is between the electrode part of the first word line and the first connecting extending part of the first word line, and where the second connecting extending part of the second word line is between the electrode part of the second word line and the first connecting extending part of the second word line.

According to an aspect of the present disclosure, there is provided a semiconductor memory device comprising a peri-gate structure on a substrate; a shielding conductive pattern that is on the peri-gate structure and includes a shielding conductive plate and a plurality of shielding conductive protruding parts that extend from the shielding conductive plate and in a first direction; bit lines that are on the shielding conductive pattern and extend in the first direction; a cell region element separation film that is on the peri-gate structure; back gate electrodes that are on the bit lines and extend in a second direction, where the back gate electrodes include a first back gate electrode and a second back gate electrode; active pattern separation structures on opposing sides of the back gate electrode; a first word line and a second word line that are on the bit line, between the back gate electrodes, between the active pattern separation structures, and extend in the second direction; a first word line contact plug electrically connected to the first word line; a second word line contact plug electrically connected to the second word line; first active patterns that are between the first back gate electrode and the first word line, electrically connected to the bit line, and spaced apart in the second direction; second active patterns that are between the second back gate electrode and the second word line, electrically connected to the bit line, and spaced apart in the second direction; and a data storage pattern that is on and electrically connected to the first active pattern and the second active pattern, where each of the first word line and the second word line includes a plug connecting part that extends beyond the back gate electrodes in the second direction, where each of the plug connecting part of the first word line and the plug connecting part of the second word line includes a first connecting extending part that extends in the second direction along a side wall of the active pattern separation structure, a second connecting extending part that is electrically connected to the first connecting extending part and that extends in the first direction, and a third connecting extending part that is electrically connected to the second connecting extending part and that extends in the second direction, where the first word line contact plug is electrically connected to the second connecting extending part of the first word line, and where the second word line contact plug is electrically connected to the second connecting extending part of the second word line.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram of a semiconductor memory device according to some embodiments.

FIG. 2 is a layout diagram of a boundary portion between a cell array region and a peripheral circuit region of FIG. 1.

FIG. 3 is a cross-sectional view taken along lines A-A and B-B of FIG. 2.

FIG. 4 is a cross-sectional view taken along lines C-C and D-D of FIG. 2.

FIG. 5 is a cross-sectional view taken along a line E-E of FIG. 2.

FIG. 6 is an enlarged view of a portion P of FIG. 3.

FIG. 7 is an enlarged view of a portion Q of FIG. 3.

FIG. 8 is an example diagram illustrating an aspect in which word lines and word line contact plugs are connected in the cell array region as in FIG. 2.

FIG. 9 is a diagram illustrating a shape of the word line around the back gate electrode.

FIG. 10 is an enlarged view of a portion R of FIG. 2.

FIGS. 11 and 12 are diagrams illustrating a semiconductor memory device according to some embodiments.

FIGS. 13 and 14 are diagrams illustrating a semiconductor device according to some embodiments.

FIGS. 15 and 16 are diagrams illustrating a semiconductor memory device according to some embodiments.

FIGS. 17 and 18 are diagrams illustrating a semiconductor memory device according to some embodiments.

FIGS. 19 and 20 are diagrams illustrating a semiconductor memory device according to some embodiments.

FIGS. 21, 22, 23, 24, 25, and 26 are diagrams illustrating a semiconductor memory device according to some embodiments.

FIG. 27 is a diagram illustrating a semiconductor memory device according to some embodiments.

FIGS. 28, 29, 30, and 31 are diagrams illustrating a semiconductor memory device according to some embodiments.

FIGS. 32, 33, 34, 35, 36, 37, 38, 39, 40, 41, 42, 43, 44, 45, 46, 47, 48, 49, 50, 51, 52, 53, 54, 55, 56, 57, 58, 59, and 60 are intermediate stage diagrams illustrating a method for fabricating a semiconductor memory device according to some embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. The phrase “an element A surrounds element B” may refer to element A at least partially surrounding element B.

Although terms such as first and second are used to describe various elements or components in the present specification, it goes without saying that these elements or components are not limited by these terms. These terms are only used to distinguish a single element or component from other elements or components. Therefore, a first element or component referred to below may be a second element or component within the technical idea of the present disclosure.

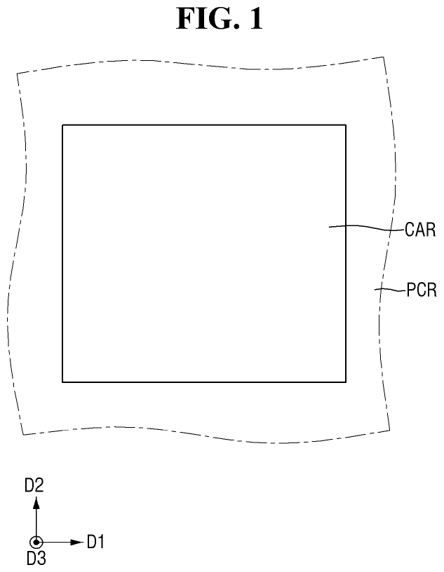

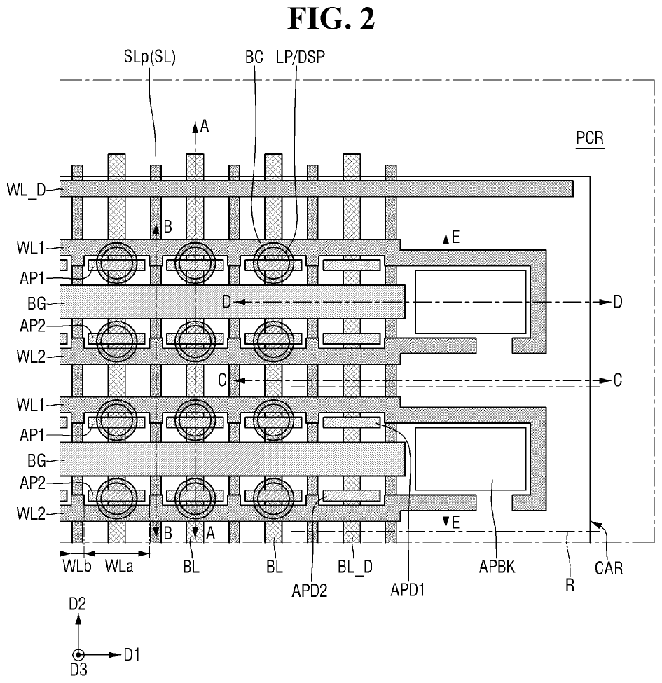

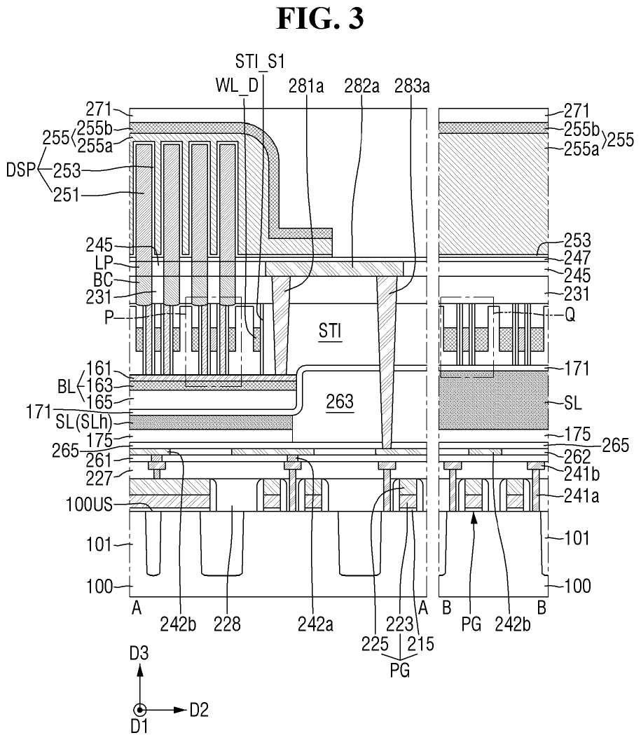

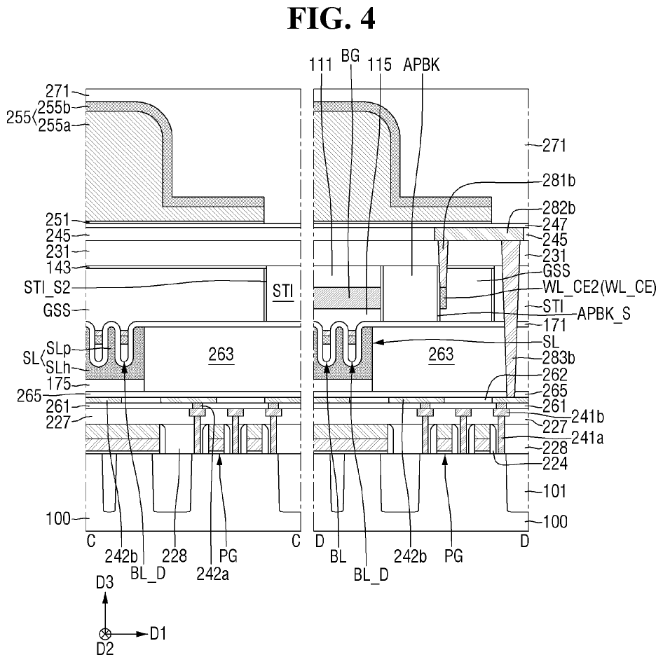

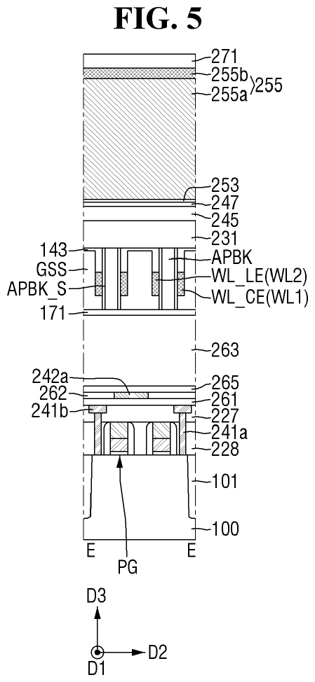

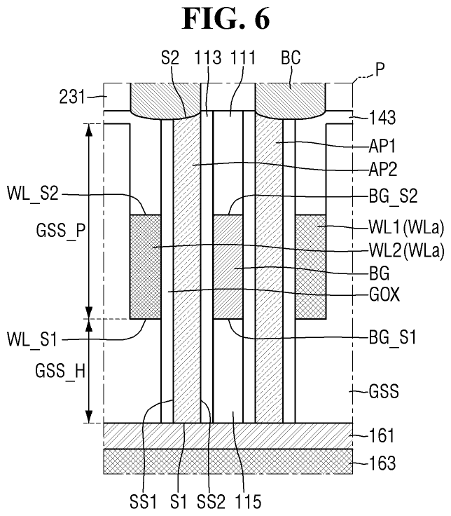

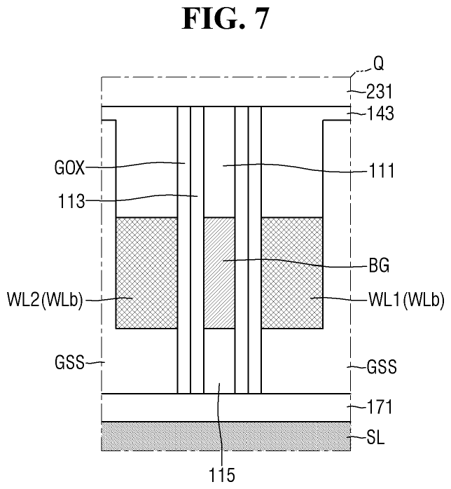

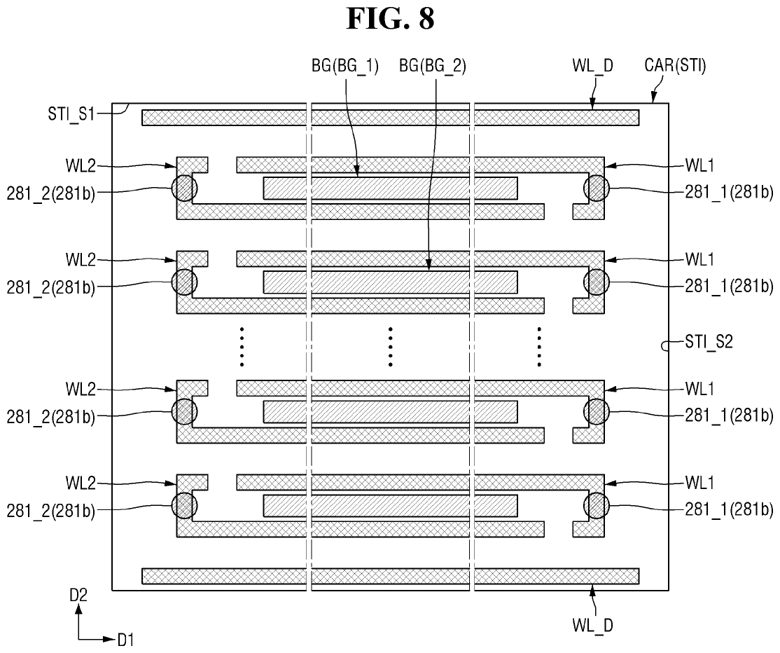

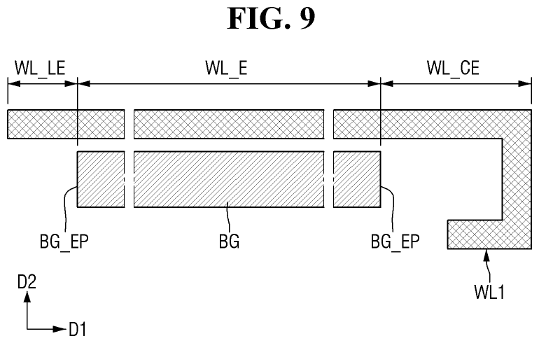

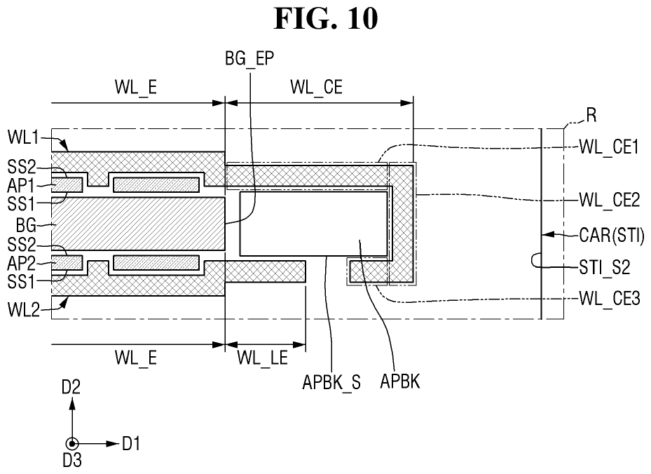

FIG. 1 is a layout diagram of a semiconductor memory device according to some embodiments. FIG. 2 is a layout diagram of a boundary portion between a cell array region and a peripheral circuit region of FIG. 1. FIG. 3 is a cross-sectional view taken along lines A-A and B-B of FIG. 2. FIG. 4 is a cross-sectional view taken along lines C-C and D-D of FIG. 2. FIG. 5 is a cross-sectional view taken along a line E-E of FIG. 2. FIG. 6 is an enlarged view of a portion P of FIG. 3. FIG. 7 is an enlarged view of a portion Q of FIG. 3. FIG. 8 is an example diagram illustrating an aspect in which word lines and word line contact plugs are connected in the cell array region as in FIG. 2. FIG. 9 is a diagram illustrating a shape of the word line around the back gate electrode. FIG. 10 is an enlarged view of a portion R of FIG. 2.

For reference, a bit line, a shielding conductive pattern, a contact pattern, a landing pad, and a data storage pattern are not shown in FIG. 10.

The semiconductor memory device according to an embodiment of the present disclosure may include memory cells including a vertical channel transistor (VCT).

Referring to FIGS. 1 to 10, the semiconductor memory device according to some embodiments may include bit lines BL, word lines WL1 and WL2, back gate electrodes BG, a shielding conductive pattern SL, active patterns AP1 and AP2, active pattern separation structures APBK, and data storage patterns DSP.

The substrate 100 may be a silicon substrate, or may include other materials, for example, but not limited to, silicon germanium, indium antimonide, lead telluride, indium arsenide, indium phosphide, gallium arsenide, or gallium antimonide.

The substrate 100 may include an upper side 100US. An element separation film 101 may be disposed in the substrate 100. The element separation film 101 may define an active region in the substrate 100. The element separation film 101 includes an insulating material.

The substrate 100 may include a cell array region CAR in which a data storage pattern DSP is disposed, and a peripheral circuit region PCR defined around the cell array region CAR. The cell region element separation film STI may be disposed on the peripheral circuit region PCR of the substrate 100. In a plan view, the cell region element separation film STI may define the cell array region CAR of the substrate 100.

A peri-gate structure PG may be disposed on the substrate 100. For example, the peri-gate structure PG may be disposed on the upper side 100US of the substrate. The peri-gate structure PG may be disposed over the cell array region CAR and the peripheral circuit region PCR. In other words, a part of the peri-gate structure PG is disposed in the cell array region CAR of the substrate 100, and the rest of the peri-gate structure PG may be disposed in the peripheral circuit region PCR of the substrate 100.

The peri-gate structure PG may be included in a sensing transistor, a transfer transistor, a drive transistor, etc. For example, the peri-gate structure PG included in the sensing transistor may be disposed on the substrate 100 of the cell array region CAR, but the location of the sensing transistor is not limited thereto. The types of transistors of the peripheral circuits disposed on the substrate 100 of the cell array region CAR may vary based on the design placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, but is not limited to, at least one of metal oxide, metal oxynitride, metal silicon oxide, and metal silicon oxynitride.

The peri-lower conductive pattern 223 and the peri-upper conductive pattern 225 may each include a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, a two-dimensional (2D) material, and metal. In the semiconductor memory device according to some embodiments, the two-dimensional material may be a metallic material and/or a semiconductor material. The 2D material may include a 2D allotrope or a 2D compound, and may include, but is not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials. Although the peri-gate structure PG is shown to include a plurality of conductive patterns, the embodiment is not limited thereto.

A peri-gate spacer 224 may be disposed on the side wall of the peri-gate structure PG. The peri-gate spacer 224 includes an insulating material.

Although not shown, the peri-gate structure PG may further include a peri-gate mask pattern disposed on the peri-upper conductive pattern 225. The peri-gate mask pattern includes an insulating material.

The first peri-lower insulating film 227 and the second peri-lower insulating film 228 are disposed on the upper side 100US of the substrate. The first peri-lower insulating film 227 and the second peri-lower insulating film 228 each include an insulating material.

A peri-contact plug 241a and a peri-wiring line 241b may be disposed in the first peri-lower insulating film 227 and the second peri-lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different elements, the present disclosure is not limited thereto. A boundary between the peri-contact plug 241a and the peri-wiring line 241b may not be divided (i.e., the peri-contact plug 241a and the peri-wiring line 241b are unitary). The peri-contact plug 241a and the peri-wiring line 241b each include a conductive material.

The first peri-upper insulating film 261 and the second peri-upper insulating film 262 may be disposed on the peri-contact plug 241a and the peri-wiring line 241b. The first peri-upper insulating film 261 and the second peri-upper insulating film 262 each include an insulating material. In one variation, an insulating film formed of a single film may be disposed on the peri-contact plug 241a and the peri-wiring line 241b.

Peri-connecting structures may be connected to the peri-wiring line 241b. The peri-connecting structures may include a peri-connecting via 242a and a peri-connecting wiring 242b. The peri-connecting via 242a and the peri-connecting wiring 242b each include a conductive material.

Although the peri-connecting via 242a and the peri-connecting wiring 242b are shown as being different elements, the present disclosure is not limited thereto. Although the peri-connecting structures 242a and 242b are shown to include one peri-connecting wiring 242b disposed on one metal level, this is only for convenience of explanation, and the embodiment is not limited thereto. The peri-connecting structures 242a and 242b may include a plurality of peri-connecting wirings 242b disposed on different metal levels from each other.

The third peri-upper insulating film 265 may be disposed on the peri-connecting structures 242a and 242b. The third peri-upper insulating film 265 includes an insulating material.

Shielding structures may be disposed on substrate 100. For example, the shielding structures may be disposed on the peri-connecting structures 242a and 242b.

The shielding structures may include a shielding conductive patterns SL and shielding insulating films. The shielding insulating films may include a shielding insulating liner 171 and a shielding insulating capping film 175.

The shielding conductive pattern SL may include a shielding conductive plate SLh and a shielding conductive protruding pattern SLp. The shielding conductive plate SLh may have a flat plate shape. The shielding conductive plate SLh may be disposed on the cell array region CAR. A part of the shielding conductive plate SLh may be disposed over the peripheral circuit region PCR.

The shielding conductive protruding pattern SLp may extend from the shielding conductive plate SLh in a third direction D3. For example, the third direction D3 may be a vertical direction perpendicular to the substrate 100.

Each shielding conductive protruding pattern SLp may extend toward word lines WL1 and WL2. Each shielding conductive protruding pattern SLp may extend in a second direction D2. Each shielding conductive protruding pattern SLp may be adjacent to each other in a first direction D. For example, the first direction D1 and the second direction D2 may be a horizontal direction that is horizontal to the substrate 100.

The shielding insulating capping film 175 may be disposed on the third peri-upper insulating film 265. The shielding insulating capping film 175 may be disposed between the third peri-upper insulating film 265 and the shielding conductive pattern SL.

The shielding insulating liner 171 may be disposed on the shielding conductive pattern SL. The shielding insulating liner 171 may extend along profiles of the shielding conductive plate SLh and the shielding conductive protruding pattern SLp. The shielding insulating liner 171 does not extend along the side wall of the shielding conductive pattern SL. The side wall of the shielding conductive pattern SL may define a boundary of the shielding conductive pattern SL. The shielding conductive pattern SL may be disposed between the shielding conductive liner 171 and the shielding insulating capping film 175.

A part of the shielding insulating liner 171 may extend along the upper side of the first upper insulating film 263. The first upper insulating film 263 may be disposed on the third peri-upper insulating film 265. The first upper insulating film 263 may cover or overlap the side walls of the shielding insulating capping film 175 and the side walls of the shielding conductive pattern SL.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, a two-dimensional material, and a metal. The shielding insulating liner 171, the shielding insulating capping film 175, and the first upper insulating film 263 each include an insulating material. The boundary between the shielding insulating liner 171 and the first upper insulating film 263 may not be divided depending on the materials included in the shielding insulating liner 171 and the first upper insulating film 263 (i.e., the shielding insulating liner 171 and the first upper insulating film 263 may be unitary).

Although not shown, a bonding insulating film may be disposed between the shielding insulating capping film 175 and the third peri-upper insulating film 265, and between the first upper insulating film 263 and the third peri-upper insulating film 265. The bonding insulating film may include, for example, but not limited to, silicon carbonitride (SiCN).

The bit lines BL may be disposed on the substrate 100. The bit lines BL may be disposed on the shielding conductive pattern SL. The bit line BL may extend long in the second direction D2. Adjacent bit lines BL may be spaced apart in the first direction D1.

Each bit line BL may be disposed on the shielding conductive plate SLh. The bit line BL may be disposed between shielding conductive protruding patterns SLp adjacent to each other in the first direction D1.

Each bit line BL may extend from the cell array region CAR to the peripheral circuit region PCR. Ends of each bit line BL may be disposed on the peripheral circuit region PCR. A part of the bit line BL may overlap a cell region element separation film STI that at least partially surrounds the cell array region CAR in the third direction D3.

A dummy bit line BL_D may be disposed on the substrate 100. The dummy bit line BL_D may be disposed on the shielding conductive pattern SL.

The dummy bit line BL_D may extend in the second direction D2. For example, the dummy bit line BL_D may be disposed at an outer corner of the cell array region CAR. The bit lines BL may be disposed between the dummy bit lines BL_D disposed along the outer corner of the cell array region CAR.

The dummy bit line BL_D may be disposed on the shielding conductive plate SLh. The dummy bit line BL_D may be disposed between shielding conductive protruding patterns SLp that are adjacent in the first direction D1.

The dummy bit line BL_D may extend from the cell array region CAR to the peripheral circuit region PCR. The end of the dummy bit line BL_D may be disposed on the peripheral circuit region PCR. For example, the dummy bit line BL_D may be disposed in a portion of the cell array region CAR that overlaps the back gate electrodes BG in the third direction D3. In other words, a part of the dummy bit line BL_D may overlap the back gate electrodes BG in the third direction D3. In a plan view, the dummy bit line BL_D may intersect the back gate electrode BG. In one variation, the dummy bit line BL_D may not include a portion that overlaps the back gate electrode BG in the third direction D3.

In one variation, a plurality of dummy bit lines BL_D may be disposed along the boundary between the cell array region CAR and the peripheral circuit region PCR. The plurality of dummy bit lines BL_D may be disposed at an outer corner from the strap line BG_SL. As another example, the dummy bit line BL_D may not be disposed on the cell array region CAR.

The bit line BL and the dummy bit line BL_D may include a semiconductor pattern 161, a metal pattern 163, and a line mask pattern 165 stacked in this order. In one variation, the bit line BL and the dummy bit line BL_D may each include one of a semiconductor pattern 161 and a metal pattern 163.

The dummy bit line BL_D has the same structure as that of the bit line BL. Although a width of the dummy bit line BL_D in the first direction D1 is shown as being the same as a width of the bit line BL in the first direction D1, the embodiment is not limited thereto. The width of the dummy bit line BL_D in the first direction D1 may be larger than the width of the bit line BL in the first direction D1.

The bit line BL and the dummy bit line BL_D may include conductive bit lines. The conductive bit line may be a film including a conductive material among the bit line BL and the dummy bit line BL_D. The conductive bit line may include, for example, a semiconductor pattern 161 and a metal pattern 163.

The semiconductor pattern 161 may include a conductive semiconductor material. The conductive semiconductor material may be, for example, a semiconductor material doped with impurities. The semiconductor pattern 161 may include at least one of poly silicon, poly silicon germanium, poly germanium, amorphous silicon, amorphous silicon germanium, and amorphous germanium. The metal pattern 163 may include a conductive material including metal. The metal pattern 163 may include, for example, at least one of conductive metal nitride, conductive metal silicon nitride, metal carbonitride, conductive metal silicide, conductive metal oxide, a two-dimensional material, and a metal. A line mask pattern 165 may include an insulating material, such as silicon nitride or silicon oxynitride.

The cell region element separation film STI may be disposed on the substrate 100. The cell region element separation film STI may be spatially separated from the upper side 100US of the substrate. The cell region element separation film STI may be disposed on the first upper insulating film 263. The shielding insulating liner 171 may be disposed between the cell region element separation film STI and the first upper insulating film 263.

The cell region element separation film STI may include a first cell region side wall STI_S1 and a second cell region side wall STI_S2. The first cell region side wall STI_S1 may extend in the first direction D1. The second cell region side wall STI_S2 may extend in the second direction D2.

In a plan view, the cell region element separation film STI may define a cell array region CAR that includes the word lines WL1 and WL2, the back gate electrodes BG, the active patterns AP1 and AP2, the active pattern separation structure APBK, and the like are disposed. In other words, the word lines WL1 and WL2, the back gate electrodes BG, the active patterns AP1 and AP2, and the active pattern separation structures APBK may be disposed in the cell array region CAR. Although the cell region element separation film STI is shown as being a single film, the embodiment is not limited thereto. The cell region element separation film STI includes an insulating material.

The first active patterns AP1 and the second active patterns AP2 may be disposed on each bit line BL. The first active patterns AP1 and the second active patterns AP2 may be disposed alternately along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. The first active patterns AP1 may be spaced apart from the second active patterns AP2 in the second direction D2. The first active patterns AP1 and the second active patterns AP2 may be two-dimensionally arranged along the first direction D1 and the second direction D2 that intersect each other.

For example, the first active pattern AP1 and the second active pattern AP2 may each be made of a single crystal semiconductor material. As an example, the first active pattern AP1 and the second active pattern AP2 may each be made of single crystal silicon.

The first active pattern AP1 and the second active pattern AP2 each have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on the first and second sides S1 and S2. Further, the width of the first active pattern AP1 may be the same as the width of the second active pattern AP2.

The width of the first active pattern AP1 and the width of the second active pattern AP2 may range from several nm to several tens of nm. For example, the width of the first active pattern AP1 and the width of the second active pattern AP2 may be, but is not limited to, 1 nm to 30 nm, such as 1 nm to 10 nm. The length of each of the first and second active patterns AP1 and AP2 may be greater than the line width of the bit line BL. That is, the length of each of the first and second active patterns AP1 and AP2 may be greater than the width of the bit line BL in the first direction D1.

Each of the first active pattern AP1 and the second active pattern AP2 includes a first side S1 and a second side S2 that are opposite to each other in the third direction D3. For example, the first sides S1 of the first and second active patterns AP1 and AP2 face the bit line BL. The second sides S2 of the first and second active patterns AP1 and AP2 face the contact pattern BC.

The first sides S1 of the first and second active patterns AP1 and AP2 are connected to the bit line BL. For example, the first sides S1 of the first and second active patterns AP1 and AP2 may be connected to the semiconductor pattern 161 of the bit line BL. In one variation, when the semiconductor pattern 161 is omitted, the first sides S1 of the first and second active patterns AP1 and AP2 may be connected to the metal pattern 163. The second sides S2 of the first and second active patterns AP1 and AP2 may be connected to the contact pattern BC.

Each of the first active pattern AP1 and the second active pattern AP2 may include a first side wall SS1 and a second side wall SS2 that are opposite to each other in the second direction D2. The second side wall SS2 of the first active pattern AP1 may face the first side wall SS1 of the second active pattern AP2.

The second side wall SS2 of the first active pattern AP1 may be adjacent to the first word line WL1. The first side wall SS1 of the second active pattern AP2 may be adjacent to the second word line WL2.

Although not shown, each of the first and second active patterns AP1 and AP2 may include a first dopant region adjacent to the bit line BL and a second dopant region adjacent to the contact pattern BC. Each of the first active pattern AP1 and the second active pattern AP2 may include a channel region between the first dopant region and the second dopant region. The first dopant region and the second dopant region are regions in which a dopant is doped in the first active pattern AP1 and the second active pattern AP2. In one variation, each of the first active pattern AP1 and the second active pattern AP2 may not include at least one of the first dopant region and the second dopant region.

At the time of operation of the semiconductor memory device, the channel regions of the first and second active patterns AP1 and AP2 may be controlled by the first and second word lines WL1 and WL2 and the back gate electrode BG. Since the first and second active patterns AP1 and AP2 are made of a single crystal semiconductor material, leakage current characteristics of the semiconductor memory device may be improved.

The first dummy active patterns APD1 and the second dummy active patterns APD2 may be disposed on the dummy bit line BL_D. The first dummy active patterns APD1 and the second dummy active patterns APD2 may be alternately disposed in the second direction D2.

The first dummy active pattern APD1 may be spaced apart from the first active pattern AP1 in the first direction D1. The first active pattern AP1 and the first dummy active pattern APD1 may be arranged in the first direction D1. The second dummy active pattern APD2 may be spaced apart from the second active pattern AP2 in the first direction D1. The second active pattern AP2 and the second dummy active pattern APD2 may be arranged in the first direction D1.

Although not shown, the first dummy active pattern APD1 and the second dummy active pattern APD2 may be in contact with the dummy bit line BL.

The second active pattern AP2 and the second dummy active pattern APD2 will be explained as an example. A length of the second active pattern AP2 in the first direction D1 may be the same as a length of the second dummy active pattern APD2 in the first direction D1. In one variation, the length of the second active pattern AP2 in the first direction D1 may be shorter/less than the length of the second dummy active pattern APD2 in the first direction D1.

Although the first dummy active pattern APD1 and the second dummy active pattern APD2 are shown as not being connected to the data storage pattern DSP, the embodiment is not limited thereto. In one variation, the first dummy active pattern APD1 and the second dummy active pattern APD2 may be connected to the data storage pattern DSP.

The description of the first dummy active pattern APD1 and the second dummy active pattern APD2 may be substantially the same as the description of the first active pattern AP1 and the second active pattern AP2.

The back gate electrodes BG may be disposed on the bit line BL and the shielding conductive pattern SL. The back gate electrodes BG may be disposed on the dummy bit line BL_D.

The back gate electrodes BG may be spaced apart from each other in the second direction D2. The back gate electrodes BG may be spaced apart at regular intervals. Each back gate electrode BG may extend in the first direction D1 across the bit line BL.

Each back gate electrode BG includes terminal ends BG_EP spaced apart in the first direction D1. Each back gate electrode BG may include a long side wall extending in the first direction D1, and a single side wall extending in the second direction D2. The terminal end BG_EP of the back gate electrode may be located on an end side wall of the back gate electrode BG.

Each back gate electrode BG may be disposed between the first active pattern AP1 and the second active pattern AP2 that are adjacent to each other in the second direction D2. The first active pattern AP1 and the second active pattern AP2 may be spaced apart from each other in the second direction D2 with the back gate electrode BG interposed therebetween. That is to say, the first active pattern AP1 may be disposed on one side of each back gate electrode BG, and the second active pattern AP2 may be disposed on the other side of each back gate electrode BG. A height of the back gate electrode BG in the third direction D3 may be smaller/less than heights of the first and second active patterns AP1 and AP2.

Each back gate electrode BG may be disposed between the first side wall SS1 of the first active pattern AP1 and the second side wall SS2 of the second active pattern AP2. Each back gate electrode BG may be disposed on the first side wall SS of the first active pattern AP1 and the second side wall SS2 of the second active pattern AP2.

The first active pattern AP1 may be disposed between the first word line WL1 and the back gate electrode BG. The second active pattern AP2 may be disposed between the second word line WL2 and the back gate electrode BG. A pair of first word line WL1 and second word line WL2 may be disposed between the back gate electrodes BG adjacent to each other in the second direction D2.

The first dummy active pattern APD1 may be disposed between the first word line WL1 and the back gate electrode BG. The second dummy active pattern APD2 may be disposed between the second word line WL2 and the back gate electrode BG.

The back gate electrode BG may include a first side BG_S1 and a second side BG_S2 that are opposite to each other in the third direction D3. The first side BG_S1 of the back gate electrode is closer to the bit line BL than the second side BG_S2 of the back gate electrode. The first side BG_S1 of the back gate electrode may face the bit line BL.

The back gate electrode BG includes a conductive material, and may include, for example, at least one of a conductive semiconductor material, conductive metal nitride, conductive metal silicon nitride, metal carbonitride, conductive metal silicide, conductive metal oxide, a two-dimensional material, and metals.

A voltage is applied to the back gate electrode BG at the time of operation of the semiconductor memory device, and a threshold voltage of the vertical channel transistor may be adjusted. The threshold voltage of the vertical channel transistor is adjusted, and leakage current characteristics may be inhibited from deteriorating.

The back gate separation pattern 111 may be disposed between the first active pattern AP1 and the second active pattern AP2 that are adjacent to each other in the second direction D2. The back gate separation pattern 111 may extend in the first direction D1 along with the back gate electrode BG. The back gate separation pattern 111 may be disposed on the second side BG_S2 of the back gate electrode.

The back gate separation pattern 111 may include, for example, a silicon oxide film, a silicon oxynitride film or a silicon nitride film. The back gate separation pattern 111 may be formed at the same level as a gate capping pattern 143, which will be described later. Here, “the same level” means that the patterns are formed by the same fabricating process. The back gate separation pattern 111 may be formed of the same material as the gate capping pattern 143.

A back gate insulating pattern 113 may be disposed between the back gate electrode BG and the first active pattern AP1, and between the back gate electrode BG and the second active pattern AP2. The back gate insulating pattern 113 may be disposed between the back gate separation pattern 111 and the first active pattern AP1, and between the back gate separation pattern 111 and the second active pattern AP2. The back gate insulating pattern 113 may include, for example, a silicon oxide film, a silicon oxynitride film, a high dielectric constant insulating film having a higher dielectric constant than a silicon oxide film or a combination thereof.

The back gate capping pattern 115 may be disposed between the bit line BL and the back gate electrode BG. The back gate capping pattern 115 may be disposed between the first active pattern AP1 and the second active pattern AP2 that are adjacent to each other in the second direction D2. The back gate capping pattern 115 may extend in the first direction D1 along with the back gate electrode BG. The back gate capping pattern 115 may be disposed on the first side BG_S1 of the back gate electrode.

The back gate capping pattern 115 may be formed of an insulating material. The back gate capping pattern 115 may include, for example, at least one of a silicon oxide film, a silicon oxynitride film and a silicon nitride film.

The active pattern separation structures APBK may be disposed on both sides of the back gate electrode BG in the first direction D1. Each back gate electrode BG may be disposed between the active pattern separation structures APBK spaced apart in the first direction D1. The active pattern separation structures APBK spaced apart in the first direction D1 may be aligned with each back gate electrode BG in the first direction D1.

The active pattern separation structure APBK may be disposed to be adjacent to the terminal end BG_EP of the back gate electrode. The active pattern separation structure APBK faces the terminal end BG_EP of the back gate electrode. The active pattern separation structure APBK may be spaced apart from the cell region element separation film STI.

The active pattern separation structure APBK may be formed of an insulating material. Based on the materials included in the active pattern separation structure APBK and the back gate insulating pattern 113, the boundary between the active pattern separation structure APBK and the back gate insulating pattern 113 may not be divided. Also, the boundary between the active pattern separation structure APBK and the gate separation pattern GSS may not be divided depending on the materials included in the active pattern separation structure APBK and the gate separation pattern GSS.

The first word line WL1 and the second word line WL2 may be disposed on the bit line BL, the dummy bit line BL_D, and the shielding conductive pattern SL. The first word line WL1 and the second word line WL2 may be disposed on the shielding conductive protruding pattern SLp.

Each of the first word line WL1 and the second word line WL2 may extend in the first direction D1. The first word line WL1 and the second word line WL2 may be alternately arranged in the second direction D2. The shapes of the word lines WL1 and WL2 from a planar viewpoint will be described later.

The first word line WL1 may be disposed on the second side walls SS2 of the first active pattern AP1. The second word line WL2 may be disposed on the first side walls SS1 of the second active patterns AP2. The first active patterns AP1 and the second active patterns AP2 may be disposed between the first word lines WL1 and the second words lines WL2 that are adjacent to each other in the second direction D2. The first dummy active pattern APD1 and the second dummy active pattern APD2 may be disposed between the first word line WL1 and the second word line WL2 that are adjacent to each other in the second direction D2.

The first word line WL1 and the second word line WL2 may be spaced apart from the bit line BL and the contact pattern BC in the third direction D3. The first word line WL1 and the second word line WL2 may be located between the bit line BL and the contact pattern BC.

Each of the first word line WL1 and the second word line WL2 may have a width in the second direction D2. The width of the first word line WL1 and the width of the second word line WL2 on the bit line BL may be different from the width of the first word line WL1 and the width of the second word line WL2 on the shielding conductive pattern SL.

For example, each of the first word line WL1 and the second word line WL2 may include a first portion WLa of the word line and a second portion WLb of the word line. A width of the first portion WLa of the word line in the second direction D2 may be smaller/less than a width of the second portion WLb of the word line in the second direction D2. As an example, the first portion WLa of the word line may overlap the bit line BL in the third direction D3. The second portion WLb of the word line may overlap the shielding conductive line SL in the third direction D3.

Each of the first word line WL1 and the second word line WL2 may include the first portion WLa of the word line and the second portion WLb of the word line that are alternately disposed along the first direction D1. On the first word line WL1, each first active pattern AP1 may be disposed between the second portions WLb of the word lines adjacent in the first direction D1. On the second word line WL2, each second active pattern AP2 may be disposed between the second portions WLb of the word lines adjacent in the first direction D1.

The first word line WL1 and the second word line WL2 may include a first side WL_S1 and a second side WL_S2 that are opposite to each other in the third direction D3. The first sides WL_S1 of the first and second word lines are closer to the bit line BL than the second sides WL_S2 of the first and second word lines.

The first word line WL1 will be explained as an example. As an example, a height of the first word line WL1 in the third direction D3 may be the same as a height of the back gate electrode BG in the third direction D3. As another example, the height of the first word line WL1 in the third direction D3 may be greater than the height of the back gate electrode BG in the third direction D3. As yet another example, the height of the first word line WL1 in the third direction D3 may be smaller than the height of the back gate electrode BG in the third direction D3.

Furthermore, as an example, the height of the first side WL_S1 of the first word line from the upper side of the bit line BL may be the same as the height of the first side BG_S1 of the back gate electrode from the upper side of the bit line BL. As another example, the first side WL_S1 of the first word line may be higher than the first side BG_S1 of the back gate electrode. As yet another example, the first side WL_S1 of the first word line may be lower than the first side BG_S1 of the back gate electrode. For example, the semiconductor pattern 161 may include the upper side of the bit line BL. When the bit line BL does not include the semiconductor pattern 161, the metal pattern 163 may include the upper side of the bit line BL.

In addition, as an example, the height of the second side WL_S2 of the first word line from the upper side of the bit line BL may be the same as the height of the second side BG_S2 of the back gate electrode from the upper side of the bit line BL. As another example, the second side WL_S2 of the first word line may be higher than the second side BG_S2 of the back gate electrode. As yet another example, the second side WL_S2 of the first word line may be lower than the second side BG_S2 of the back gate electrode.

The first word line WL1 and the second word line WL2 include a conductive material. The first word line WL1 and the second word line WL2 may include, for example, at least one of a conductive semiconductor material, conductive metal nitride, conductive metal silicon nitride, metal carbonitride, conductive metal silicide, conductive metal oxide, a two-dimensional material, and a metal. Although the first word line WL1 and the second word line WL2 are shown as being a single conductive film, this is only for convenience of explanation, and the embodiment is not limited thereto.

The first sides WL_S1 of the first and second word lines WL1 and WL2 may be a plane. In one variation, the first sides WL_S1 of the first and second word lines WL1 and WL2 may be rounded concavely. As another example, each of the first word line WL1 and the second word line WL2 may have the form of a spacer. In other words, the first sides WL_S1 of the first and second word lines WL1 and WL2 may be rounded convexly.

The second sides WL_S2 of the first and second word lines WL1 and WL2 may be a plane. In one variation, the second sides WL_S2 of the first and second word lines WL1 and WL2 may have a concave curved surface. Although the first side BG_S1 of the back gate electrode and the second side BG_S2 of the back gate electrode are shown as being a plane, the embodiment is not limited thereto.

The dummy word line WL_D may extend along the boundary of the cell array region CAR. In the semiconductor memory device according to some embodiments, the dummy word line WL_D may extend in the first direction D1. The dummy word line WL_D may not extend in the second direction D2. The dummy word line WL_D may extend along the first cell region side wall STI_S1 of the cell region element separation film STI. The dummy word line WL_D may not extend along the second cell region side wall STI_S2 of the cell region element separation film STI. The dummy word line WL_D may be spaced apart from the first and second word lines WL1 and WL2 in the second direction D2.

The first word line WL1 will be explained as an example. In FIG. 9, the first word line WL1 may include an electrode part WL_E, a plug connecting part WL_CE, and an electrode extending part WL_LE. The electrode part WL_E of the first word line WL1 is disposed between the plug connecting part WL_CE of the first word line WL1 and the electrode extending part WL_LE of the first word line WL1. The electrode part WL_E of the first word line WL1 is directly connected to the plug connecting part WL_CE of the first word line WL1 and the electrode extending part WL_LE of the first word line WL1.

The electrode part WL_E of the first word line WL1 and the electrode extending part WL_LE of the first word line WL1 may have a linear shape extending in the first direction D1. Here, the term “linear shape” does not mean a shape having the same width and extending straight in a certain direction. The plug connecting part WL_CE of the first word line WL1 may have a non-linear shape, such as a hook shape, for example.

The electrode part WL_E of the first word line WL1 may extend in the first direction D1 along the back gate electrode BG. The electrode part WL_E of the first word line WL1 may be a portion of the first word line WL1 that overlaps the back gate electrode BG in the second direction D2. The first active pattern AP1 and the first dummy active pattern APD1 may be disposed between the back gate electrode BG and the electrode part WL_E of the first word line WL1. The electrode part WL_E of the first word line WL1 may include a first portion WLa of the word line and a second portion WLb of the word line.

The back gate electrode BG may include first and second terminal ends BG_EP that are spaced apart in the first direction D1. The electrode extending part WL_LE of the first word line WL1 may extend beyond the back gate electrode BG in the first direction D1. For example, the electrode extending part WL_LE of the first word line WL1 may be a portion of the first word line WL1 that extends beyond the first terminal end BG_EP of the back gate electrode BG in the first direction D1.

The plug connecting part WL_CE of the first word line WL1 may extend beyond the back gate electrode BG in the first direction D1. For example, the plug connecting part WL_CE of the first word line WL1 may be a portion of the first word line WL1 that extends beyond the second terminal end BG_EP of the back gate electrode BG in the first direction D1.

In FIGS. 9 and 10, the plug connecting part WL_CE of the first word line WL1 may be disposed along a part of the side wall APBK_S of the active pattern separation structure. The plug connecting part WL_CE of the first word line WL1 may include a first connecting extending part WL_CE1, a second connecting extending part WL_CE2, and a third connecting extending part WL_CE3. The second connecting extending part WL_CE2 is disposed between the first connecting extending part WL_CE1 and the third connecting extending part WL_CE3. The second connecting extending part WL_CE2 is directly connected to the first connecting extending part WL_CE1 and the third connecting extending part WL_CE3.

The first connecting extending part WL_CE1 of the first word line WL1 may be directly connected to the electrode part WL_E of the first word line WL1. The first connecting extending part WL_CE1 of the first word line WL1 is disposed between the electrode part WL_E of the first word line WL1 and the second connecting extending part WL_CE2 of the first word line WL1. The first connecting extending part WL_CE1 of the first word line WL1 may extend in the first direction D1. The first connecting extending part WL_CE1 of the first word line WL1 may extend along the side wall APBK_S of the active pattern separation structure extending in the first direction D1.

The second connecting extending part WL_CE2 of the first word line WL1 may extend in the second direction D2. The second connecting extending part WL_CE2 of the first word line WL1 may extend along the side wall APBK_S of the active pattern separation structure extending in the second direction D2.

The second connecting extending part WL_CE2 of the first word line WL1 may extend in the second direction D2 from the first connecting extending part WL_CE1 of the first word line WL1. For example, the second connecting extending part WL_CE2 of the first word line WL1 may extend in a direction from the second side wall SS2 of the first active pattern AP1 toward the first side wall SS1 of the first active pattern AP1.

The second connecting extending part WL_CE2 of the first word line WL1 may overlap the back gate electrode BG in the first direction D1. The second connecting extending part WL_CE2 of the first word line WL1 may be located on an extension line of the back gate electrode BG extending in the first direction D1.

The third connecting extending part WL_CE3 of the first word line WL1 may extend in the first direction D1. The third connecting extending part WL_CE3 of the first word line WL1 may extend from the second connecting extending part WL_CE2 of the first word line WL1 toward the back gate electrode BG. The third connecting extending part WL_CE3 of the first word line WL1 may extend along the side wall APBK_S of the active pattern separation structure extending in the first direction D1.

The second word line WL2 may include an electrode part WL_E, a plug connecting part WL_CE, and an electrode extending part WL_LE. The electrode part WL_E of the second word line WL2 and the electrode extending part WL_LE of the second word line WL2 may have a linear shape extending in the first direction D1. The plug connecting part WL_CE of the second word line WL2 may have a non-linear shape, such as a hook shape.

The plug connecting part WL_CE of the second word line WL2 may include a first connecting extending part WL_CE1, a second connecting extending part WL_CE2, and a third connecting extending part WL_CE3. The second connecting extending part WL_CE2 of the second word line WL2 may extend in the second direction D2 from the first connecting extending part WL_CE1 of the second word line WL2. For example, the second connecting extending part WL_CE2 of the second word line WL2 may extend from the first side wall SS1 of the second active pattern AP2 toward the second side wall SS2 of the second active pattern AP2.

Since the description of the electrode part WL_E of the second word line WL2, the plug connecting part WL_CE of the second word line WL2, and the electrode extending part WL_LE of the second word line WL2 may be substantially the same as the description of the first word line WL1, the description thereof will not be provided.

In FIGS. 8 to 10, the back gate electrodes BG may include a first back gate electrode BG_1 and a second back gate electrode BG_2 that are adjacent to each other in the second direction D2. A pair including one of the first word lines WL1 and one of the second word lines WL2 is disposed between the first back gate electrode BG_1 and the second back gate electrode BG_2. The first word line WL1 is closer to the first back gate electrode BG_1 than the second word line WL2. The second word line WL2 is closer to the second back gate electrode BG_2 than the first word line WL1.

The plug connecting part WL_CE of the first word line WL1 does not overlap the plug connecting part WL_CE of the second word line WL2 in the second direction D2. The plug connecting part WL_CE of the first word line WL1 may overlap the electrode extending part WL_LE of the second word line WL2 in the second direction D2. The plug connecting part WL_CE of the second word line WL2 may overlap the electrode extending part WL_LE of the first word line WL1 in the second direction D2.

The second connecting extending part WL_CE2 of the first word line WL1 may overlap the first back gate electrode BG_1 in the first direction D1. The second connecting extending part WL_CE2 of the second word line WL2 may overlap the second back gate electrode BG_2 in the first direction D1.

In FIGS. 8 and 10, the dummy word line WL_D may include terminal ends spaced apart in the first direction D1. The terminal end of the dummy word line WL_D may be closer to the second cell region side wall STI_S2 of the cell region element separation film STI than the second connecting extending part WL_CE2 of the first and second word lines WL1 and WL2. In one variation, a distance by which the terminal end of the dummy word line WL_D is spaced apart from the second cell region side wall STI_S2 may be the same as a distance by which the second connecting extending part WL_CE2 of the first word line WL1 is spaced apart from the second cell region side wall STI_S2. The distance by which the terminal end of the dummy word line WL_D is spaced apart from the second cell region side wall STI_S2 may be the same as the distance by which the second connecting extending part WL_CE2 of the second word line WL2 is spaced apart from the second cell region side wall STI_S2.

A gate insulating pattern GOX may be disposed between the first word line WL1 and the first active pattern AP1, and between the second word line WL2 and the second active pattern AP2. The gate insulating pattern GOX may be disposed between the first word line WL1 and the first dummy active pattern APD1, and between the second word line WL2 and the second dummy active pattern APD2. The gate insulating pattern GOX may be disposed between the first word line WL1 and the active pattern separation structure APBK, and between the second word line WL2 and the active pattern separation structure APBK. The gate insulating pattern GOX may be disposed between the dummy word line WL_D and the cell region element separation film STI.

The gate insulating pattern GOX may include a silicon oxide film, a silicon oxynitride film, a high dielectric constant insulating film having a higher dielectric constant than a silicon oxide film or a combination thereof.

The gate insulating pattern GOX may extend along the second side wall SS2 of the first active pattern AP1, and may extend along the first side wall SS1 of the second active pattern AP2. In the semiconductor memory device according to some embodiments, from the viewpoint of a cross-sectional view, the gate insulating pattern GOX between the first active pattern AP1 and the first word line WL1 may be separated from the gate insulating pattern GOX between the second active pattern AP2 and the second word line WL2.

The gate capping pattern 143 may be disposed between the first word line WL1 and the contact pattern BC, and between the second word line WL2 and the contact pattern BC. The gate capping pattern 143 may cover or overlap the second side WL_S2 of the first and second word lines WL1 and WL2.

The gate separation pattern GSS may be disposed on the bit line BL. The gate separation pattern GSS may be disposed on the bit line BL. The gate separation pattern GSS may be disposed on the dummy bit line BL_D. The gate separation pattern GSS may be disposed between the bit line BL and the contact pattern BC. The gate separation pattern GSS may be in contact with the bit line BL.

The gate separation pattern GSS may be disposed between the first word line WL1 and the second word line WL2 that are adjacent to each other in the second direction D2. The first word line WL1 and the second word line WL2 may be separated by the gate separation pattern GSS. The gate separation pattern GSS may extend in the first direction D1 between the first word line WL1 and the second word line WL2. In the semiconductor memory device according to some embodiments, the gate separation pattern GSS may be disposed between the cell region element separation film STI and the second connecting extending part WL_CE2 of the first and second word lines WL1 and WL2.

The first word line WL1 may be disposed between the gate separation pattern GSS and the first active pattern AP1. The second word line WL2 may be disposed between the gate separation pattern GSS and the second active pattern AP2.

The gate separation pattern GSS may include a horizontal part GSS_H and a protruding part GSS_P. The protruding part GSS_P of the gate separation pattern may extend from the horizontal part GSS_H of the gate separation pattern in the third direction D3.

The horizontal part GSS_H of the gate separation pattern may be closer to the bit line BL than the protruding part GSS_P of the gate separation pattern. The horizontal part GSS_H of the gate separation pattern may be in contact with the bit line BL. A width of the horizontal part GSS_H of the gate separation pattern in the second direction D2 is greater than a width of the protruding part GSS_P of the gate separation pattern in the second direction D2.

The protruding part GSS_P of the gate separation pattern may be disposed between the side walls of the first word line WL1 and the second word line WL2 that face each other. The horizontal part GSS_H of the gate separation pattern may cover or overlap the first sides WL_S1 of the first and second word lines WL1 and WL2.

The first word line WL1 and the second word line WL2 may be disposed on the horizontal part GSS_H of the gate separation pattern. The first word line WL1 and the second word line WL2 may have a shape that conforms to the shape of the horizontal part GSS_H of the gate separation pattern. The first word line WL1 and the second word line WL2 may be disposed between the horizontal part GSS_H of the gate separation pattern and the contact pattern BC.

The gate separation pattern GSS may be made of an insulating material. In one variation, the gate separation pattern GSS may include a plurality of insulating films.

The contact patterns BC may extend into the contact interlayer insulating film 231. The contact pattern BC may be connected to each of the first active pattern AP1 and the second active pattern AP2. The contact patterns BC may be connected to the second sides S2 of the first and second active patterns AP1 and AP2. In a planar view, each contact pattern BC may have various shapes, such as a circle, an ellipse, a rectangle, a square, a rhombus, and a hexagon. The contact interlayer insulating film 231 may be disposed on the cell region element separation film STI.

The contact patterns BC may not be connected to the first and second dummy active patterns APD1 and APD2. In one variation, the contact patterns BC may be connected to the first and second dummy active patterns APD1 and APD2.

The contact pattern BC may include a conductive material. The contact pattern BC may include, for example, at least one of a conductive semiconductor material, conductive metal nitride, conductive metal silicon nitride, metal carbonitride, conductive metal silicide, conductive metal oxide, a two-dimensional material, and a metal. The contact interlayer insulating film 231 may include an insulating material.

Landing pads LP may be disposed on the contact pattern BC. In a planar view, the landing pads LP may have various shapes, such as a circle, an ellipse, a rectangle, a square, a rhombus, and a hexagon.

The pad separation insulating film 245 may be disposed on the contact interlayer insulating film 231. The pad separation insulating film 245 may be disposed between the landing pads LP. The pad separation insulating film 245 may separate the landing pads LP from each other. In a planar view, the landing pads LP may be arranged in the form of a matrix along the first direction D1 and the second direction D2. An upper side of the landing pad LP may be substantially coplanar with the upper side of the pad separation insulating film 245.

The landing pad LP includes a conductive material, and may include, for example, at least one of a conductive semiconductor material, conductive metal nitride, conductive metal silicon nitride, metal carbonitride, conductive metal silicide, conductive metal oxide, a two-dimensional material, and metal. The pad separation insulating film 245 includes an insulating material.

A bit line contact plug 281a may be connected to the bit line BL. The bit line contact plug 281a may be disposed in the contact interlayer insulating film 231 and the cell region element separation film STI. The bit line contact plug 281a is connected to the conductive bit line.

The word line contact plug 281b may be connected to the first and second word lines WL1 and WL2. The word line contact plug 281b may be disposed in the contact interlayer insulating film 231 and the gate separation pattern GSS. The word line contact plug 281b may be connected to the second side WL_S2 of the first and second word lines WL1 and WL2.

The word line contact plug 281b may be connected to the plug connecting parts WL_CE of the first and second word lines WL1 and WL2. For example, the word line contact plug 281b may be connected to the second connecting extending part WL_CE2 of the first and second word lines WL1 and WL2.

In FIGS. 5, 8, and 10, the word line contact plug 281b may include a first word line contact plug 281_1 and a second word line contact plug 281_2. The first word line contact plug 281_1 may be connected to the first word line WL1. The first word line contact plug 281_1 may be connected to the second connecting extending part WL_CE2 of the first word line WL1. The second word line contact plug 281_2 may be connected to the second word line WL2. The second word line contact plug 281_2 may be connected to the second connecting extending part WL_CE2 of the second word line WL2.

The first word line contact plug 281_1 may be adjacent to the second word line contact plug 281_2 in the first direction D1. The back gate electrode BG may be disposed between the first word line contact plug 281_1 and the second word line contact plug 281_2. The first word line contact plug 281_1 and the second word line contact plug 281_2 may be disposed on an extension line of the back gate electrode BG extending in the first direction D1.

The first word line contact plugs 281_1 may be arranged in the second direction D2. The first word line contact plugs 281_1 may be arranged in a line along one of the second cell region side walls STI_S2. The second word line contact plugs 281_2 may be arranged in the second direction D2. The second word line contact plugs 281_2 may be arranged in a line along the other side wall of the second cell region STI_S2.

The first and second upper connecting wirings 282a and 282b may be disposed in the pad separation insulating film 245. The first upper connecting wiring 282a may be connected to the bit line contact plug 281a. The second upper connecting wiring 282b may be connected to the word line contact plug 281b.

The first and second upper peripheral contact plugs 283a and 283b may be connected to the peri-connecting wiring 242b. The first and second upper peripheral contact plugs 283a and 283b may extend through the contact interlayer insulating film 231, the cell region element separation film STI, and the first upper insulating film 263.

The first upper peripheral contact plug 283a may connect the bit line BL and the peri-connecting wiring 242b. The second upper peripheral contact plug 283b may connect the first and second word lines WL1 and WL2 to the peri-connecting wiring 242b.

The bit line contact plug 281a, the word line contact plug 281b, the first upper connecting wiring 282a, the second upper connecting wiring 282b, the first upper peripheral contact plug 283a, and the second upper peripheral contact plug 283b each include a conductive material.

The data storage patterns DSP may be disposed on the landing pads LP, respectively. The data storage patterns DSP may be electrically connected to each of the first and second active patterns AP1 and AP2. The data storage patterns DSP may be arranged in the form of a matrix along the first direction D1 and the second direction D2, as shown in FIG. 2. The data storage patterns DSP may completely overlap or partially overlap the landing pads LP in the third direction D3. The data storage patterns DSP may be in contact with all or part of the upper sides of the landing pads LP.

As an example, the data storage patterns DSP may be a capacitor. The data storage patterns DSP may include a capacitor dielectric film 253 interposed between the storage electrodes 251 and the plate electrode 255. The storage electrode 251 may be in contact with the landing pad LP. In a planar view, the storage electrode 251 may have various shapes, such as a circle, an ellipse, a rectangle, a square, a rhombus, and a hexagon. The storage electrodes 251 may extend through the upper etching stop film 247. The upper etching stop film 247 may be disposed on the pad separation insulating pattern 245. The upper etching stop film 247 may be made of an insulating material.

The plate electrode 255 may include a lower plate electrode 255a and an upper plate electrode 255b. In one variation, the plate electrode 255 may be a single film. The storage electrode 251 and the plate electrode 255 may include, for example, at least one of a conductive semiconductor material, conductive metal nitride, conductive metal silicon nitride, metal carbonitride, conductive metal silicide, conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, combinations of the ferroelectric and antiferroelectric materials, combinations of the ferroelectric and paraelectric materials, combinations of paraelectric and antiferroelectric materials, and combinations of the ferroelectric material, the antiferroelectric material and the paraelectric material.

In one embodiment, the data storage patterns DSP may be variable resistance patterns that may be switched into two resistance states by electrical pulses applied to the memory element. For example, the data storage patterns DSP may include a phase-change material, perovskite compounds, transition metal oxide, magnetic materials, ferromagnetic materials or antiferromagnetic materials.

The second upper insulating film 271 may be disposed on the upper etching stop film 247. The second upper insulating film 271 may be disposed on the data storage pattern DSP. For example, the second upper insulating film 271 may cover or overlap the data storage pattern DSP. The second upper insulating film 271 may cover or overlap the side walls of the plate electrode 255. The second upper insulating film 271 includes an insulating material.

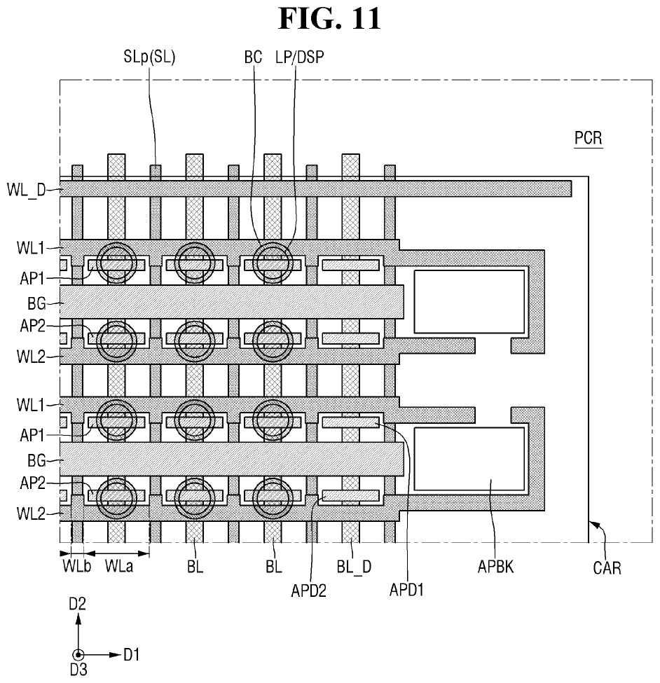

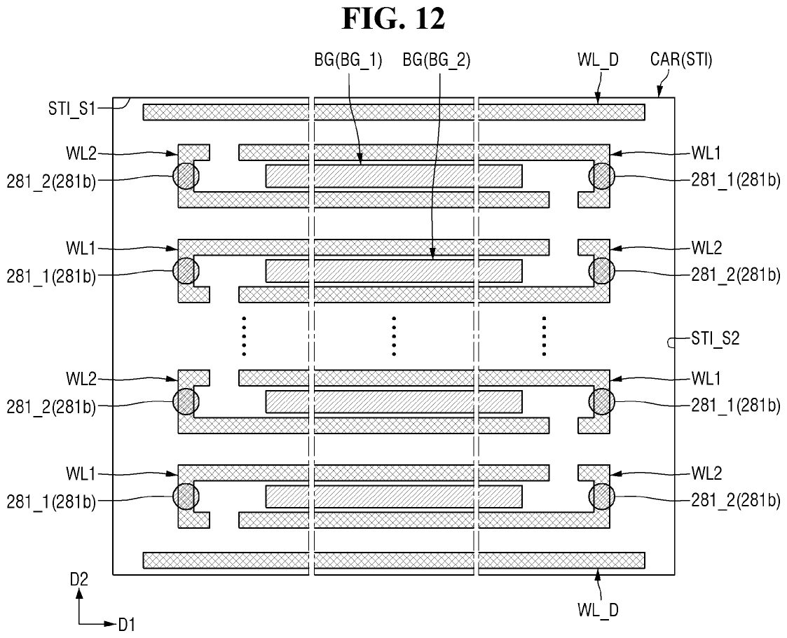

FIGS. 11 and 12 are diagrams illustrating the semiconductor memory device according to some embodiments. For convenience of explanation, elements that are different from those described with reference to FIGS. 1 to 10 will be mainly explained.

For reference, FIG. 11 is a layout diagram of a boundary portion between the cell array region and the peripheral circuit region of FIG. 1. FIG. 12 is an example diagram illustrating an aspect in which the word lines and the word line contact plugs are connected in the cell array region as in FIG. 11.

Referring to FIGS. 11 and 12, in the semiconductor device according to some embodiments, a first word line WL1 and a second word line WL2 disposed between a first back gate electrode BG_1 and a second back gate electrode BG_2 may have a symmetrical linear-shape with respect to a line extending in the first direction D1.

A plug connecting part (WL_CE of FIGS. 9 and 10) of the first word line WL1 may overlap a plug connecting part (WL_CE of FIGS. 9 and 10) of the second word line WL2 in the second direction D2. An electrode extending part (WL_LE of FIGS. 9 and 10) of the first word line WL1 may overlap an electrode extending part (WL_LE of FIGS. 9 and 10) of the second word line WL2 in the second direction D2.

The second connecting extending part WL_CE2 of the first word line WL1 may overlap the second back gate electrode BG_2 in the first direction D1. The second connecting extending part WL_CE2 of the second word line WL2 may overlap the first back gate electrode BG_1 in the first direction D1.

The first word line contact plug 281_1 may be disposed in zigzags. The second word line contact plug 281_2 may be disposed in zigzags. The first word line contact plugs 281_1 and the second word line contact plugs 281_2 may be alternately disposed along the second direction D2. The second word line contact plug 281_2 may be disposed between the first word line contact plugs 281_1 closest to each other in the second direction D2. The first word line contact plug 281_1 may be disposed between the second word line contact plugs 281_2 closest to each other in the second direction D2.

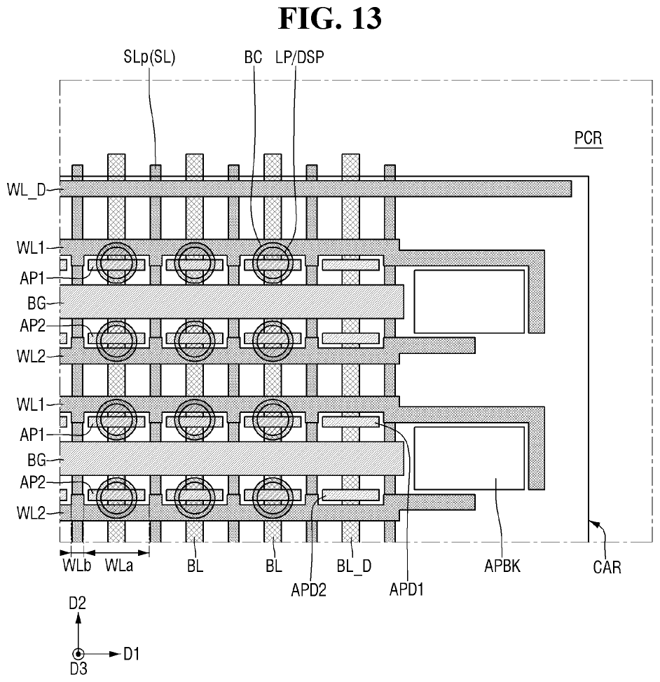

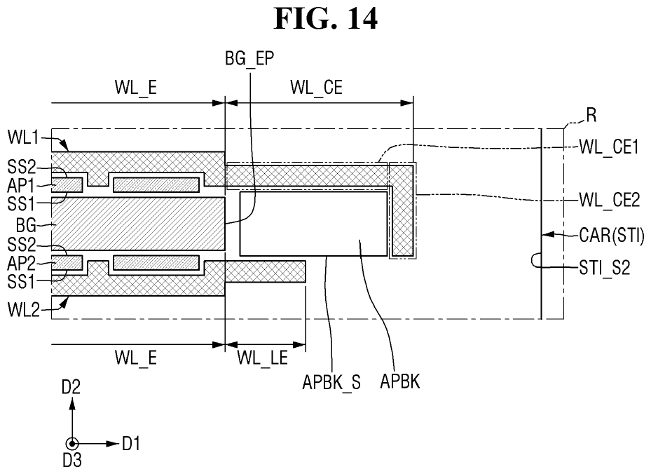

FIGS. 13 and 14 are diagrams illustrating a semiconductor device according to some embodiments. For convenience of explanation, elements that are different from those described with reference to FIGS. 1 to 10 will be mainly explained.

For reference, FIG. 13 is a layout diagram of the boundary portion between the cell array region and the peripheral circuit region of FIG. 1. FIG. 14 is an enlarged view of a portion R of FIG. 13.

Referring to FIGS. 13 and 14, in the semiconductor memory device according to some embodiments, the plug connecting part WL_CE of the first word line WL1 may have a “V” shape, for example, a hook shape.

The plug connecting part WL_CE of the first word line WL1 has a first connecting extending part WL_CE1 extending in the first direction D1, and a second connecting extending part WL_CE2 extending in the second direction D2. The plug connecting part WL_CE of the first word line WL1 does not include a third connecting extending part (WL_CE3 of FIG. 10) that extends from the second connecting extending part WL_CE2 of the first word line WL1 toward the back gate electrode BG.

The description of the plug connecting part WL_CE of the second word line WL2 may be substantially the same as the description of the plug connecting part WL_CE of the first word line WL2 described above.

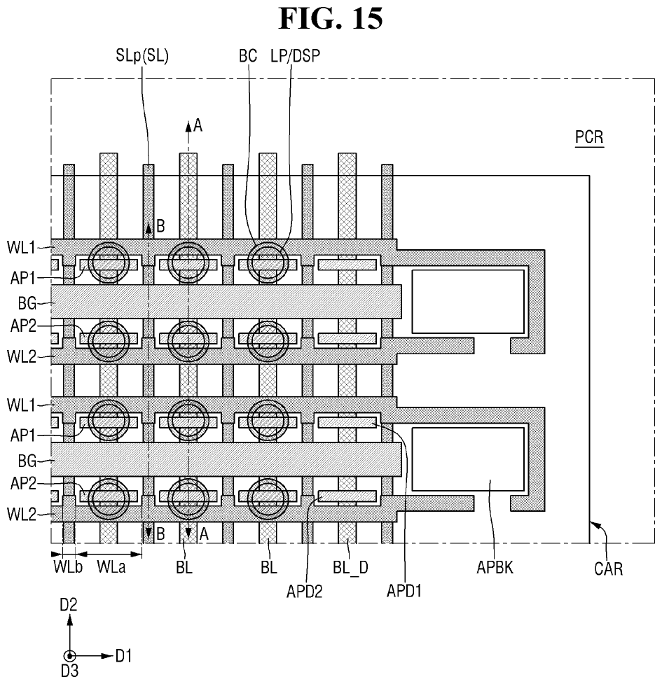

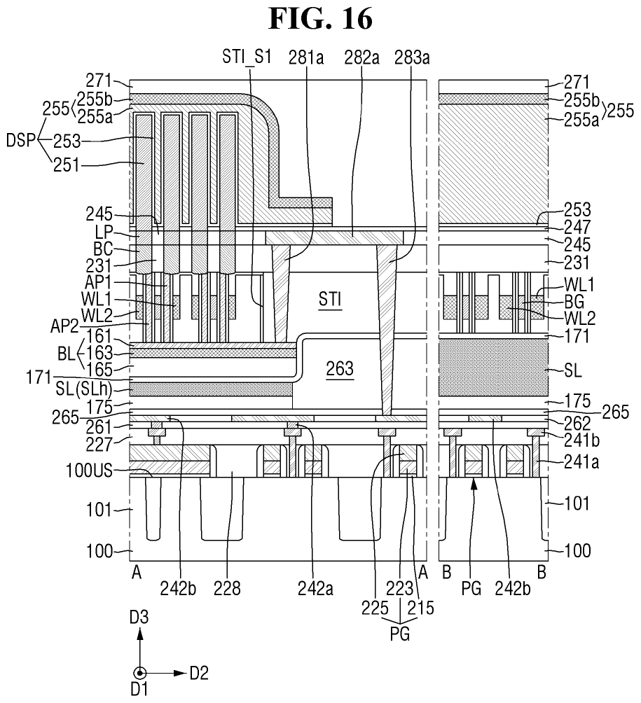

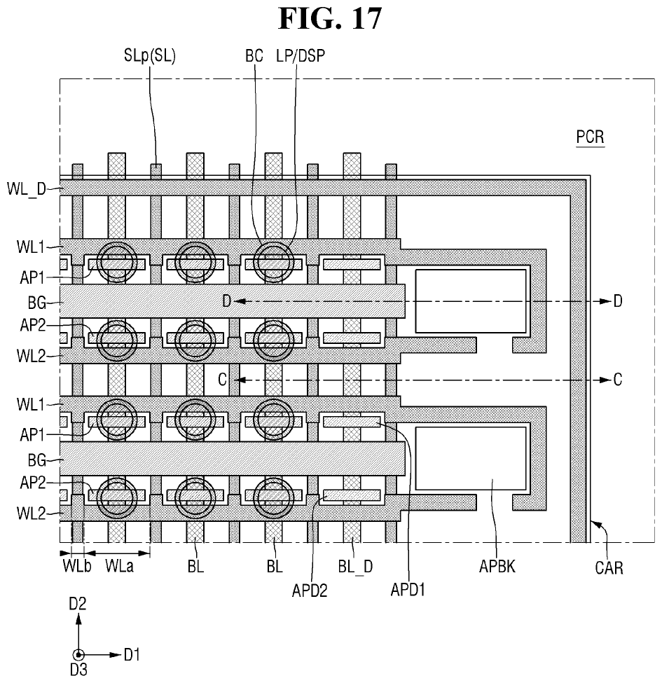

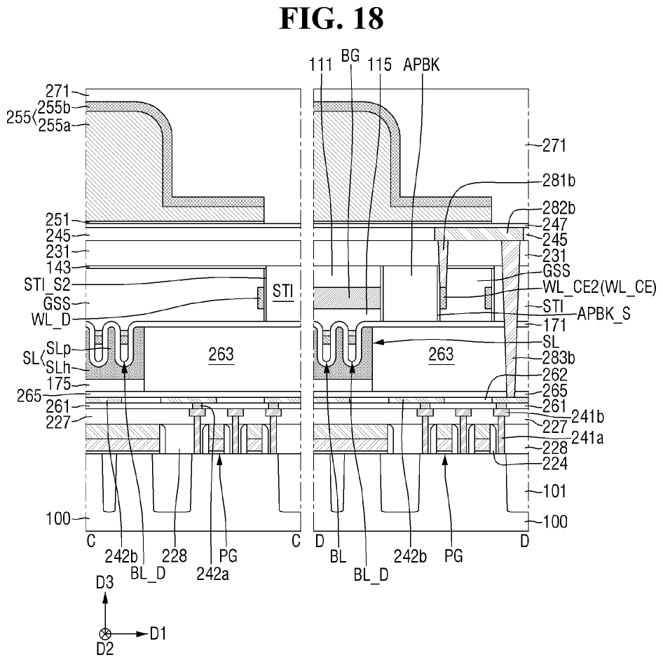

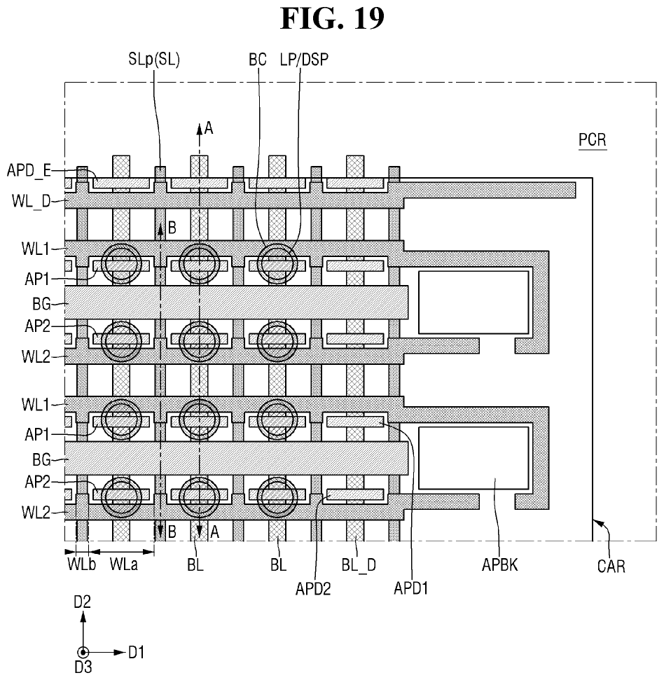

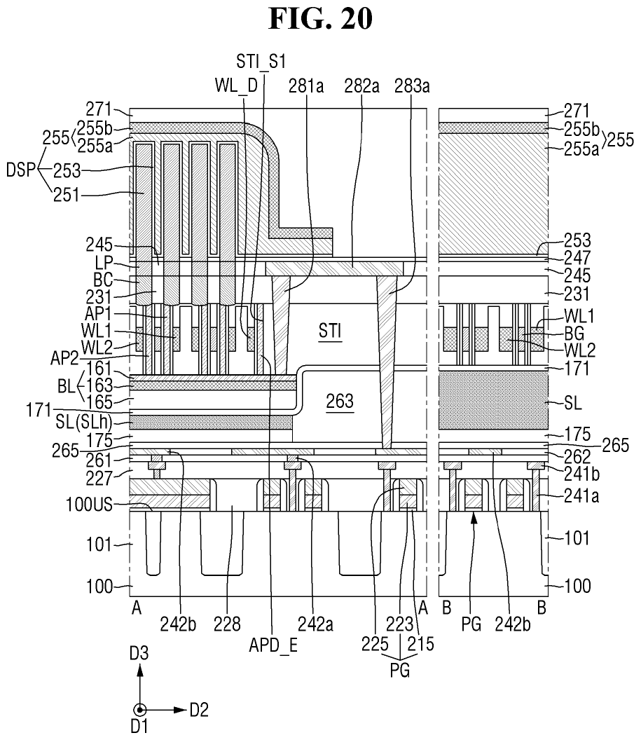

FIGS. 15 and 16 are diagrams illustrating a semiconductor memory device according to some embodiments. FIGS. 17 and 18 are diagrams illustrating the semiconductor memory device according to some embodiments. FIGS. 19 and 20 are diagrams illustrating the semiconductor memory device according to some embodiments. For convenience of explanation, elements that are different from those described with reference to FIGS. 1 to 10 will be mainly explained.

Referring to FIGS. 15 and 16, in the semiconductor memory device according to some embodiments, the dummy word line (WL_D of FIG. 2) may not be disposed along the boundary of the cell array region CAR.

The dummy word line (WL_D of FIG. 2) extending along the first cell region side wall STI_S1 of the cell region element separation film STI is not disposed in the cell region element separation film STI.

Referring to FIGS. 17 and 18, in the semiconductor memory device according to some embodiments, the dummy word line WL_D may extend along the first cell region side wall STI_S1 and the second cell region side wall STI_S2.

The dummy word line WL_D may include a portion extending in the first direction D1, and a portion extending in the second direction D2. The dummy word line WL_D may be disposed along the boundary of the cell array region CAR.

Referring to FIGS. 19 and 20, the semiconductor memory device according to some embodiments may further include boundary dummy active patterns APD_E disposed between the dummy word line WL_D and the cell region element separation film STI.

The boundary dummy active patterns APD_E may be disposed along the boundary of the cell array region CAR. The boundary dummy active patterns APD_E may be disposed along the first cell region side wall STI_S1. For example, the boundary dummy active patterns APD_E may be in contact with the cell region element separation film STI.

The boundary dummy active patterns APD_E may be spaced apart in the first direction D1. The boundary dummy active patterns APD_E may be arranged in the first direction D1. The boundary dummy active patterns APD_E may not be connected to the data storage pattern DSP.

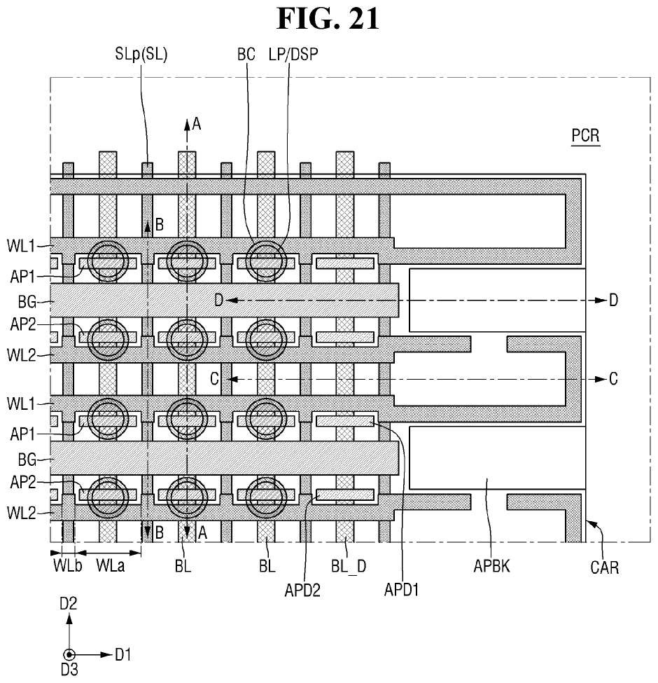

FIGS. 21 to 26 are diagrams illustrating a semiconductor memory device according to some embodiments. For convenience of explanation, elements that are different from those described with reference to FIGS. 1 to 10 will be mainly explained.

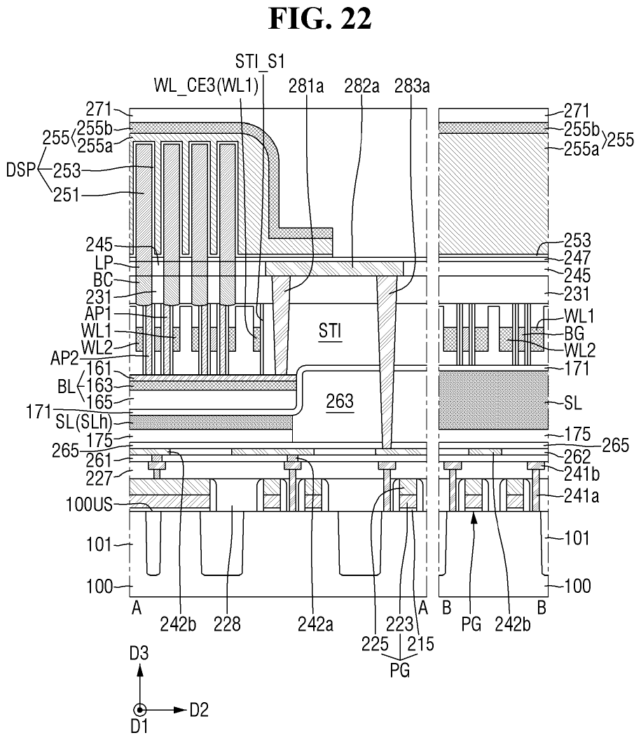

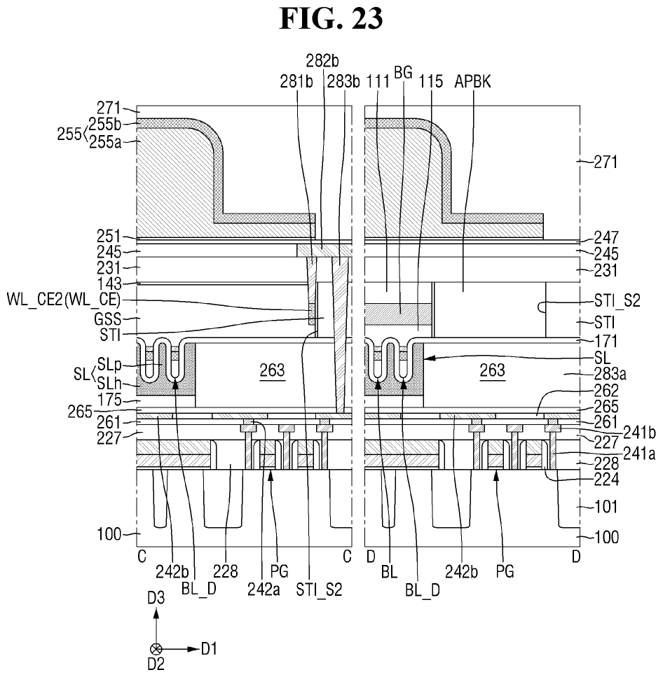

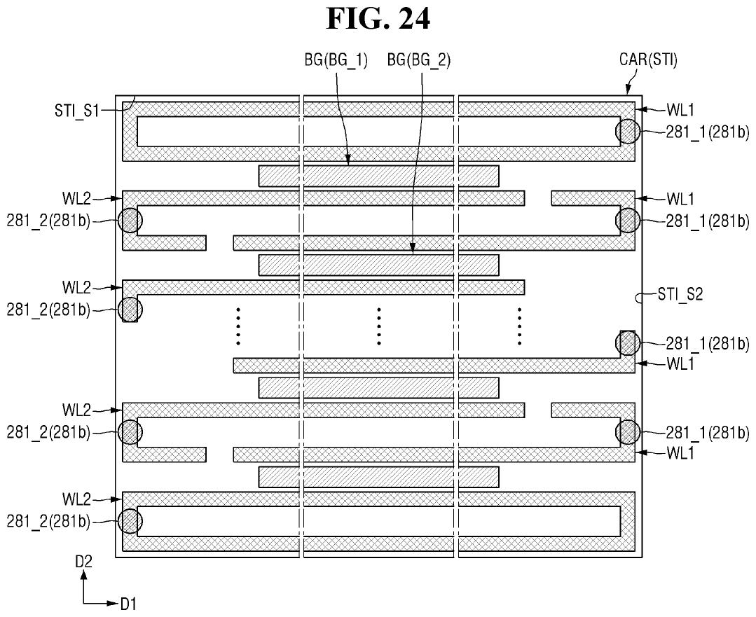

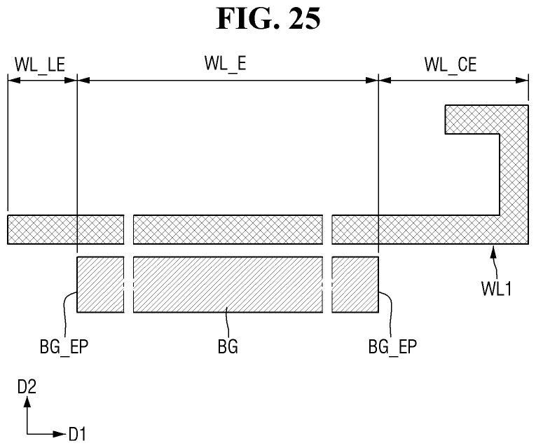

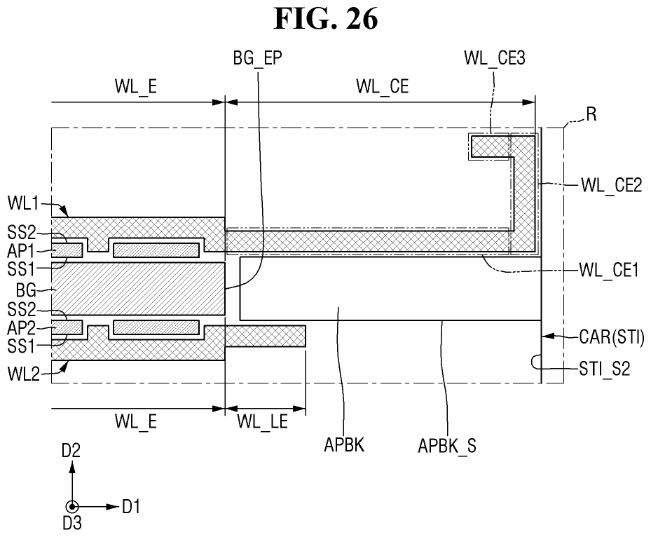

For reference, FIG. 21 is a layout diagram of the boundary portion between the cell array region and the peripheral circuit region of FIG. 1. FIG. 22 is a cross-sectional view taken along lines A-A and B-B of FIG. 21. FIG. 23 is a cross-sectional view taken along lines C-C and D-D of FIG. 21. FIG. 24 is an example diagram illustrating an aspect in which the word lines and the word line contact plugs are connected in the cell array region as in FIG. 21. FIG. 25 is a diagram illustrating the shape of the word line around the back gate electrode. FIG. 26 is an enlarged view of the portion R of FIG. 21.

Referring to FIGS. 21 to 26, in the semiconductor memory device according to some embodiments, the active pattern separation structures APBK contact the cell region element separation film STI.

Each active pattern separation structure APBK may extend from the cell region element separation film STI. Each active pattern separation structure APBK extends from the second cell region side wall STI_S2 in the second direction D2.

In the semiconductor memory device according to some embodiments, the first word line WL1 and the second word line WL2 disposed at the outermost corners of the cell array region CAR may have a loop shape. The dummy word line (WL_D of FIG. 2) extending along the boundary of the cell array region CAR may not be included in some embodiments.

In FIGS. 21, 25 and 26, the plug connecting part WL_CE of the first word line WL1 may be disposed along the side walls APBK_S of two active pattern separation structures adjacent in the second direction D2 and the second cell region side wall STI_S2. The first connecting extending part WL_CE1 of the first word line WL1 may extend in the first direction D1 along the side wall APBK_S of the active pattern separation structure. The second connecting extending part WL_CE2 of the first word line WL1 may extend in the second direction D2 along the second cell region side wall STI_S2. The third connecting extending part WL_CE3 of the first word line WL1 may extend in the first direction D1 along the side wall APBK_S of the active pattern separation structure.

The second connecting extending part WL_CE2 of the first word line WL1 may extend in the second direction D2 from the first connecting extending part WL_CE1 of the first word line WL1. For example, the second connecting extending part WL_CE2 of the first word line WL1 may extend in the direction from the first side wall SS1 of the first active pattern AP1 toward the second side wall SS2 of the first active pattern AP1.

The second connecting extending part WL_CE2 of the first word line WL1 may not overlap the back gate electrode BG in the first direction D1. The second connecting extending part WL_CE2 of the first word line WL1 is not located on an extension line along which the back gate electrode BG extends in the first direction D1.

Since the active pattern separation structure APBK is in contact with the cell region element separation film STI, the second connecting extending part WL_CE2 of the first word line WL1 is not disposed between the cell region element separation film STI and the active pattern separation structure APBK.

The description of the plug connecting part WL_CE of the second word line WL2 may be substantially the same as the description of the first word line WL1.

In FIGS. 21, and 24 to 26, the active pattern separation structures APBK may include a first active pattern separation structure and a second active pattern separation structure that are closest to each other in the second direction. The first active pattern separation structure may be aligned with the first back gate electrode BG_1 in the first direction D1. The second active pattern separation structure may be aligned with the second back gate electrode BG_2 in the first direction D1. The first back gate electrode BG_1 may be disposed between the first active pattern separation structures. The second back gate electrode BG_2 may be disposed between the second active pattern separation structures.

A pair of first word line WL1 and second word line WL2 are disposed between the first back gate electrode BG_1 and the second back gate electrode BG_2. The first word line WL1 is closer to the second back gate electrode BG_2 than the second word line WL2. The second word line WL2 is closer to the first back gate electrode BG_1 than the first word line WL1.

The electrode part WL_E of the first word line WL1 extends in the first direction D1 along the second back gate electrode BG_2. The electrode part WL_E of the second word line WL2 extends in the first direction D1 along the first back gate electrode BG_1.

The plug connecting part WL_CE of the first word line WL1 may overlap the electrode extending part WL_LE of the second word line WL2 in the second direction D2. The plug connecting part WL_CE of the second word line WL2 may overlap the electrode extending part WL_LE of the first word line WL1 in the second direction D2.

The second connecting extending part WL_CE2 of the first word line WL1 and the second connecting extending part WL_CE2 of the second word line WL2 may not overlap the first back gate electrode BG_1 in the first direction D1. The second connecting extending part WL_CE2 of the first word line WL1 and the second connecting extending part WL_CE2 of the second word line WL2 may not overlap the second back gate electrode BG_2 in the first direction D1.

The first connecting extending part WL_CE1 of the first word line WL1 may extend along the side wall APBK_S of the second active pattern separation structure extending in the first direction D1. The first connecting extending part WL_CE1 of the second word line WL2 may extend along the side wall APBK_S of the first active pattern separation structure extending in the first direction D1.

The third connecting extending part WL_CE3 of the first word line WL1 may extend along a part of the side wall APBK_S of the first active pattern separation structure extending in the first direction D1. The third connecting extending part WL_CE3 of the second word line WL2 may extend along a part of the side wall APBK_S of the second active pattern separation structure extending in the first direction D1.

The first word line contact plugs 281_1 may be arranged in a line along one of the second cell region side walls STI_S2. The second word line contact plugs 281_2 may be arranged in a line along the other of the second cell region side walls STI_S2.

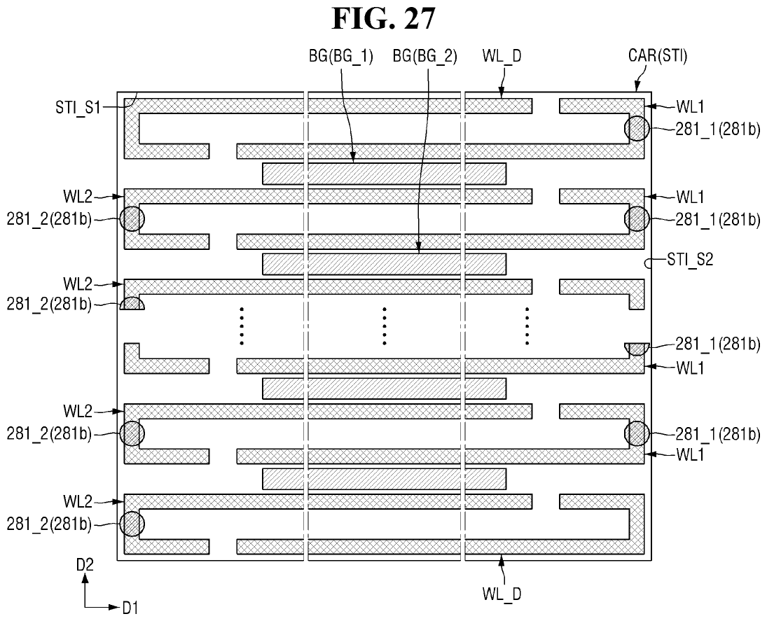

FIG. 27 is a diagram illustrating a semiconductor memory device according to some embodiments. For convenience of explanation, the explanation will focus on the elements that are different from those explained with reference to FIGS. 21 to 26.

Referring to FIG. 27, the semiconductor memory device according to some embodiments may further include a dummy word line WL_D extending along the boundary of the cell array region CAR.

For example, each dummy word line WL_D may extend along the first cell region side wall STI_S1, the second cell region side wall STI_S2, and the side wall (APBK_S of FIG. 26) of the active pattern separation structure. Each dummy word line WL_D may include a hook-shaped portion.

In one variation, each dummy word line WL_D may not include a portion extending along the second cell region side wall STI_S2 and the side wall APBK_S of the active pattern separation structure.

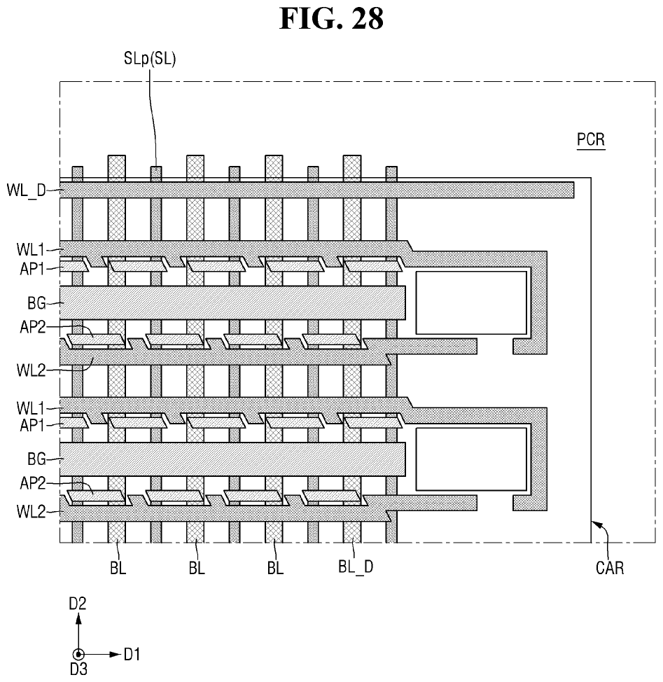

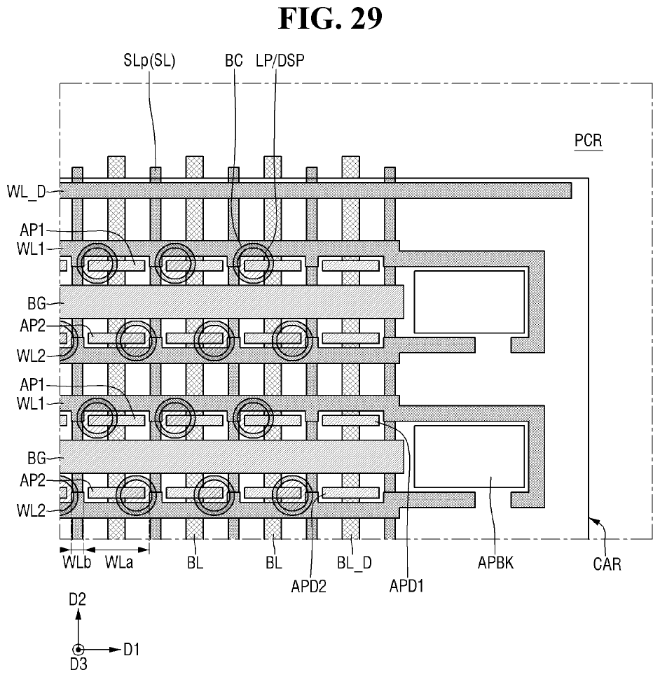

FIGS. 28 to 31 are diagrams illustrating a semiconductor memory device according to some embodiments, respectively. For convenience of explanation, the explanation will focus on the elements that are different from those explained with reference to FIGS. 1 to 27.

Referring to FIG. 28, in the semiconductor memory device according to some embodiments, the first and second active patterns AP1 and AP2 may be alternately arranged in a diagonal direction with respect to the first direction D1 and the second direction D2.

In a planar view, each of the first and second active patterns AP1 and AP2 may have a parallelogram or rhombus shape. Since the first and second active patterns AP1 and AP2 are disposed in the diagonal direction, coupling between the first and second active patterns AP1 and AP2 facing each other in the second direction D2 may be reduced.

Referring to FIG. 28, in the semiconductor memory device according to some embodiments, landing pads LP and data storage patterns DSP may be arranged in a zigzag or honeycomb form in a planar view.

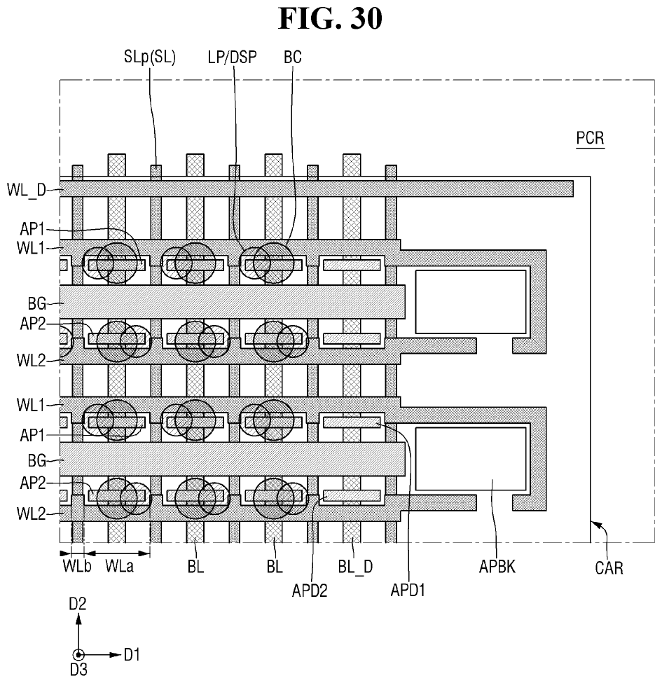

Referring to FIG. 30, in the semiconductor memory device according to some embodiments, the data storage patterns DSP may be disposed to be offset from the landing pad LP in a planar view.

Each data storage pattern DSP may be in contact with a part of the landing pad LP.

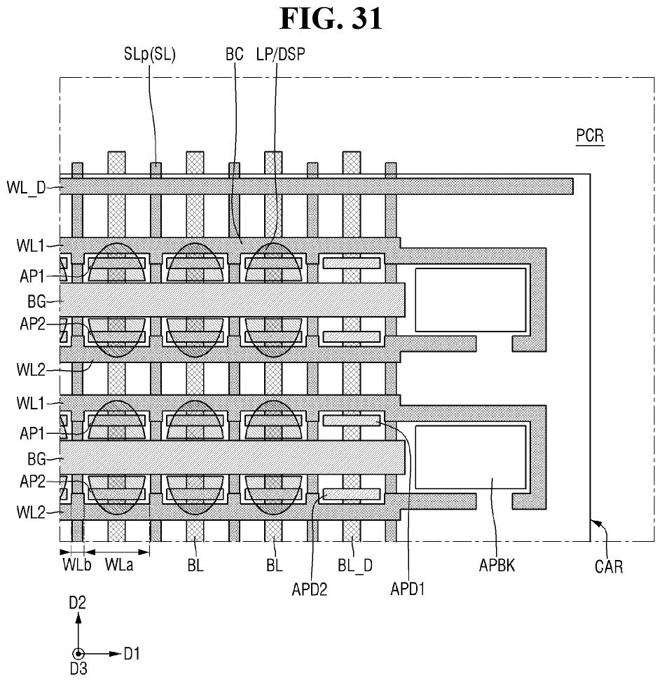

Referring to FIG. 31, in the semiconductor memory device according to some embodiments, each of the contact patterns BC disposed on the first and second active patterns AP1 and AP2 may have a semicircular shape or a semi-elliptical shape in a planar view.

The contact patterns BC may be disposed symmetrically with each other across the back gate electrode BG in a planar view.

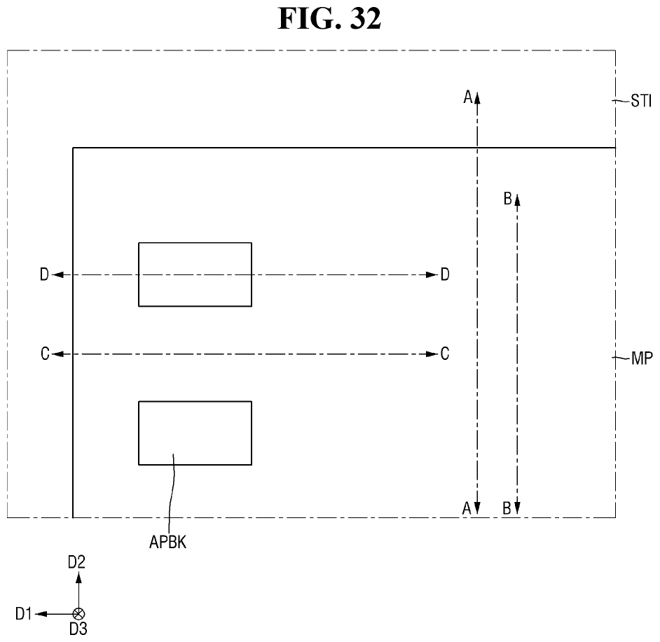

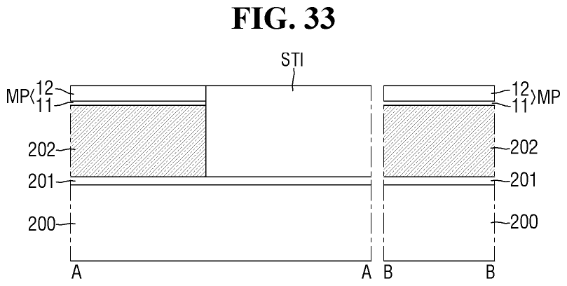

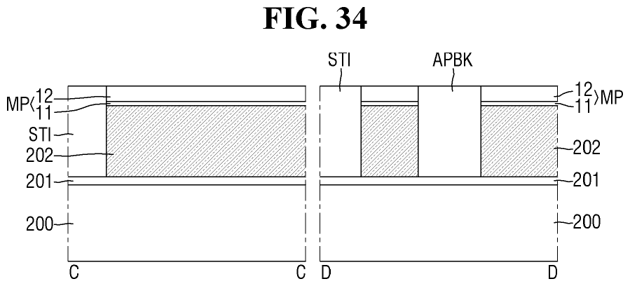

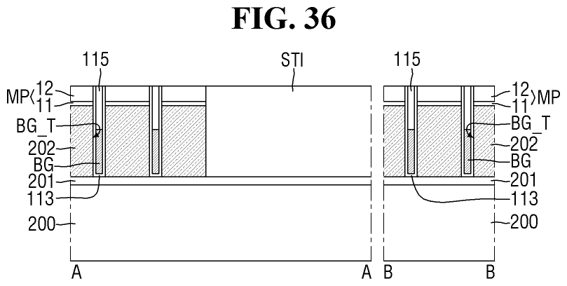

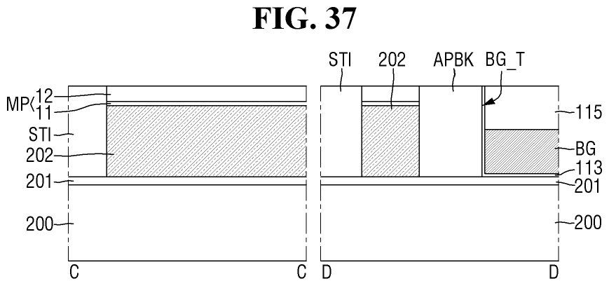

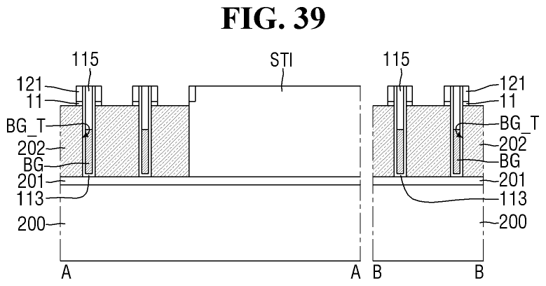

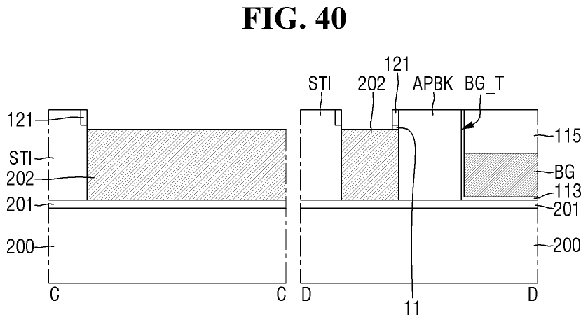

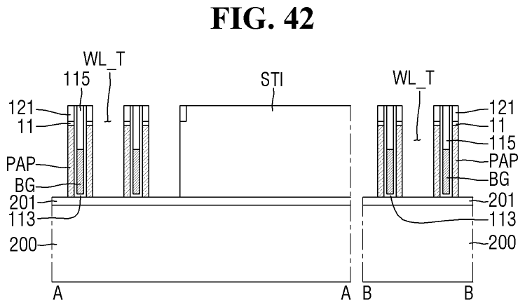

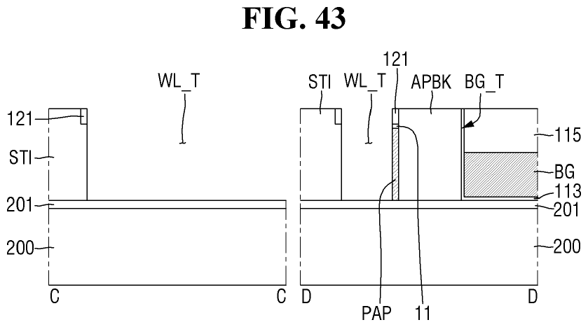

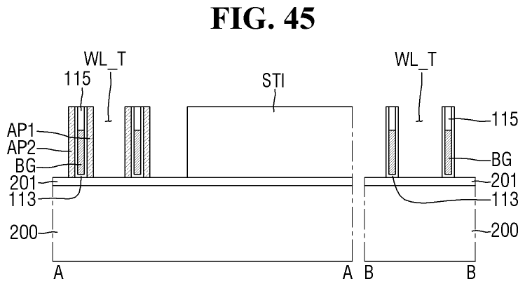

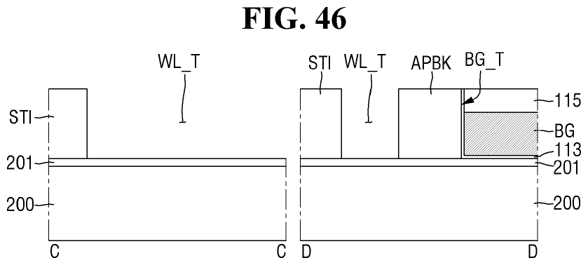

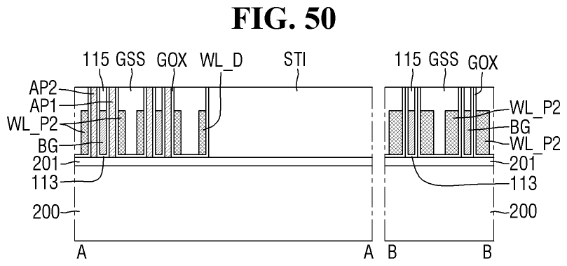

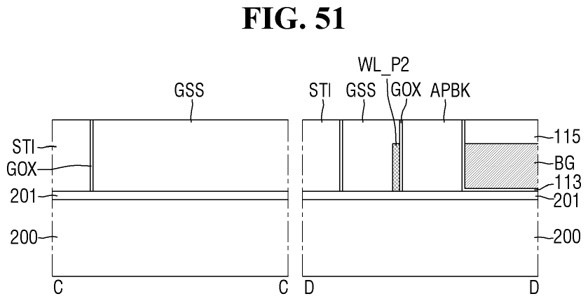

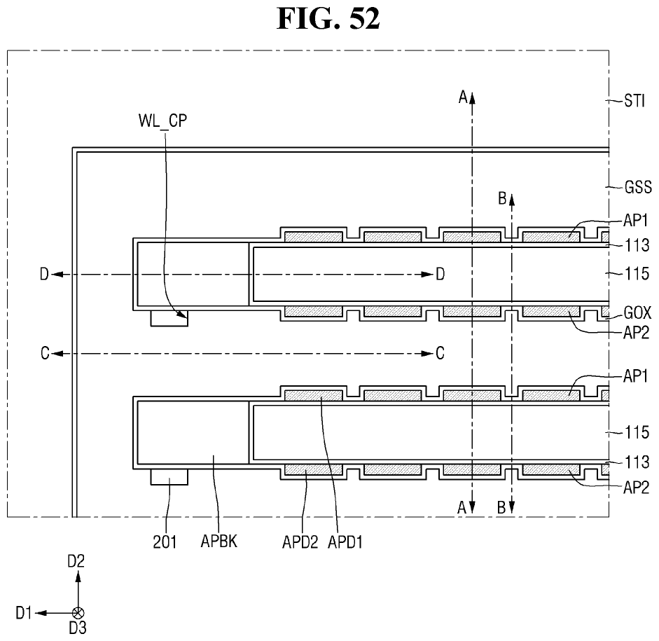

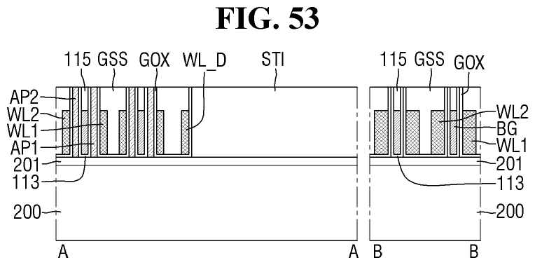

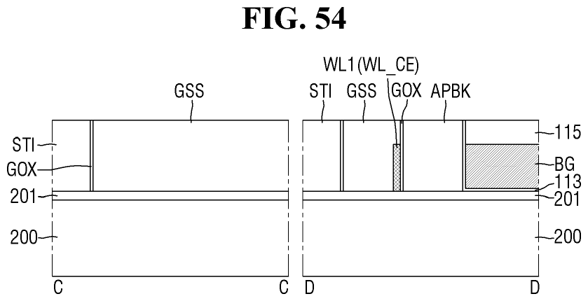

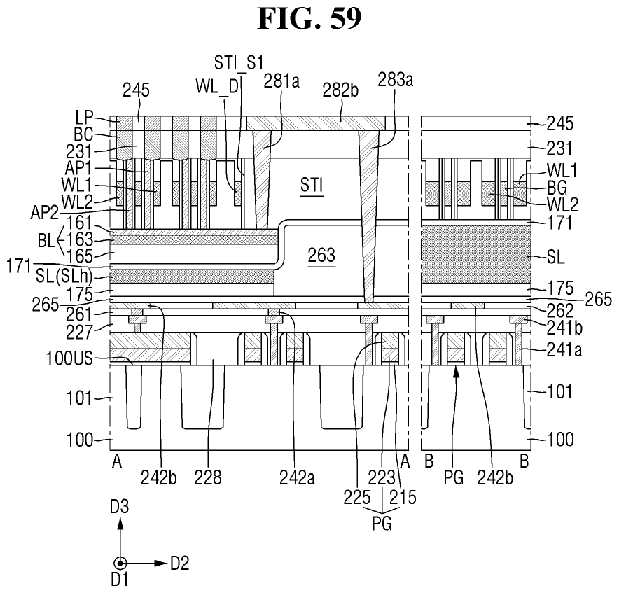

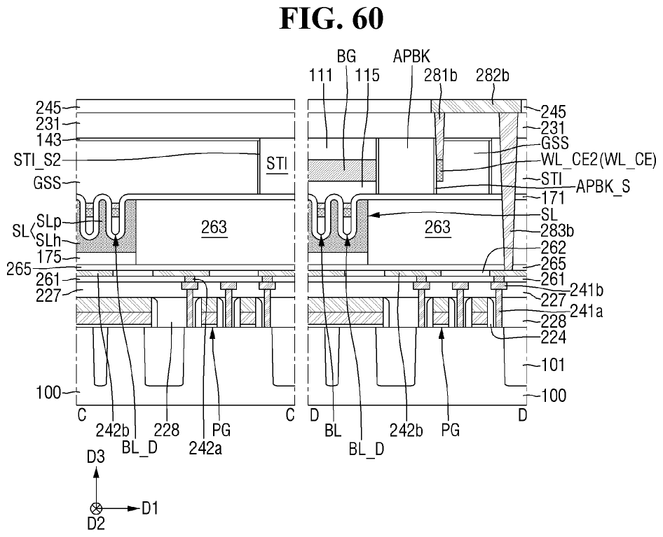

FIGS. 32 to 60 are intermediate stage diagrams illustrating a method for fabricating a semiconductor memory device according to some embodiments. The semiconductor memory device described with reference to FIGS. 1 to 10 may be fabricated in accordance with the method described herein.

Referring to FIGS. 32 to 34, a sub-substrate structure including a sub-substrate 200, a buried insulating film 201, and an active layer 202 may be provided.

The buried insulating film 201 and the active layer 202 may be provided on the sub-substrate 200. The sub-substrate 200, the buried insulating film 201 and the active layer 202 may be a silicon-on-insulator substrate (i.e., SOI substrate).

The sub-substrate 200 may include a cell array region CAR and a peripheral circuit region PCR. The sub-substrate 200 may be, for example, a silicon substrate, a germanium substrate, and/or a silicon-germanium substrate.

The buried insulating film 201 may be a buried oxide (BOX) formed by a separation by implanted oxygen (SIMOX) method or a bonding and layer transfer method. In another embodiment, the buried insulating film 201 may be an insulating film formed by a chemical vapor deposition method. The buried insulating film 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first side and a second side that are opposite to each other in the third direction D3, and the second side of the active layer 202 may be in contact with the buried insulating film 201.

A mask pattern MP may then be formed on the active layer 202. The mask pattern MP may include a lower mask film 11 and an upper mask film 12 that are sequentially stacked. The upper mask film 12 may be made of a material having etching selectivity with respect to the lower mask film 11. As an example, the lower mask film 11 may include silicon oxide, and the upper mask film 12 may include, but is not limited to, silicon nitride.

Subsequently, a cell region element separation film STI may be formed inside the active layer 202 of the peripheral circuit region PCR. The cell region element separation film STI may be formed by patterning the active layer 202 of the peripheral circuit region PCR to form an element separation trench that exposes the buried insulating film 201, and then burying an insulating material inside the element separation trench. The cell region element separation film STI may be formed to define the cell array region CAR. The upper side of the cell region element separation film STI may be substantially coplanar with the upper side of the mask pattern MP.

A plurality of active pattern separation structures APBK may be formed in the active layer 202. The active pattern separation structure APBK is disposed in the cell array region CAR. The active pattern separation structures APBK may be arranged in the second direction D2. The active pattern separation structure APBK may include, for example, silicon oxide.

The active pattern separation structure APBK may be spaced apart from the cell region element separation film STI. In one variation, the active pattern separation structure APBK may be formed to be in contact with the cell region element separation film STI.

In a plan view, the active pattern separation structure APBK is shown to be a square, but the shape is not limited thereto. In one variation, the active pattern separation structure APBK may have a shape such as a square with rounded corners, an ellipse, or a circle.

In one variation of the method, the active pattern separation structure APBK may be formed in the active layer 202 before the mask pattern MP is formed. In such a case, the mask pattern MP may be formed on the active pattern separation structure APBK.

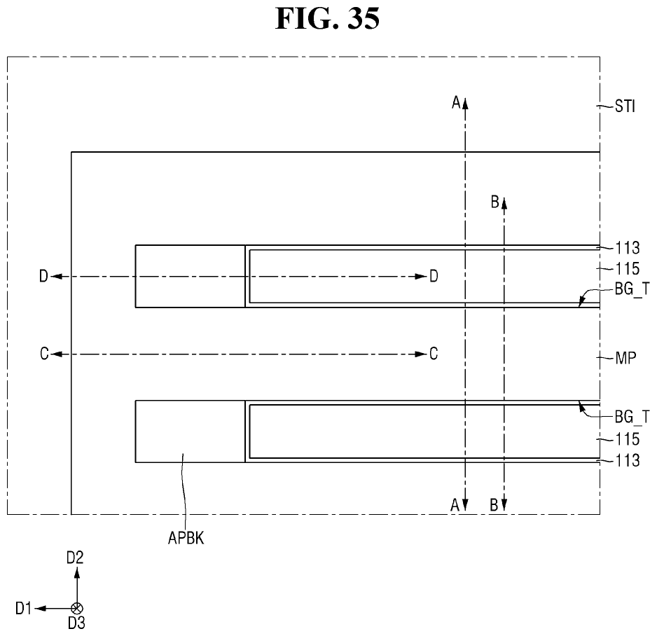

Referring to FIGS. 35 to 37, the active layer 202 of the cell array region CAR may be anisotropically etched.

Accordingly, back gate trenches BG_T extending in the first direction D1 may be formed on the active layer 202 of the cell array region CAR. The back gate trenches BG_T may expose the buried insulating film 201 and may be spaced apart at regular intervals in the second direction D2. Each back gate trench BG_T may be joined to respective active pattern separation structures APBK. The back gate trench BG_T may extend from the active pattern separation structure APBK in the first direction D1.

In one variation, at least a part of the buried insulating film 201 may be removed while the back gate trench BG_T is being formed.

Thereafter, the back gate insulating pattern 113 and the back gate electrodes BG may be formed in the back gate trench BG_T. The back gate insulating pattern 113 may be in contact with the active pattern separation structure APBK.

More specifically, the back gate insulating pattern 113 may be formed along the side wall and the bottom side of the back gate trench BG_T and the upper side of the mask pattern MP. A back gate conductive film may be formed on the back gate insulating pattern 113. The back gate conductive film may fill the back gate trench BG_T. Subsequently, the back gate conductive film may be etched to form back gate electrodes BG extending in the first direction D1. The back gate electrodes BG may partially fill the back gate trench BG_T.

Meanwhile, according to some embodiments, a gas phase doping (GPD) process or a plasma doping (PLAD) process may be performed before forming the back gate insulating pattern 113. The active layer 202 exposed by the back gate trench BG_T may be doped with impurities through the aforementioned process.

The back gate capping patterns 115 may then be formed on the back gate electrode BG.

The back gate capping pattern 115 may fill or be in the rest of the back gate trench BG_T. If the back gate capping pattern 115 and the back gate insulating pattern 113 are made up of the same material (e.g., silicon oxide), the back gate insulating pattern 113 on the upper side of the back gate mask pattern MP may be removed while the back gate capping pattern 115 is being formed.

Meanwhile, before forming the back gate capping patterns 115, the gas phase doping (GPD) process or the plasma doping (PLAD) process may be performed. Impurities may be doped into the active layer 202 through the back gate trench BG_T in which the back gate electrode BG is formed.

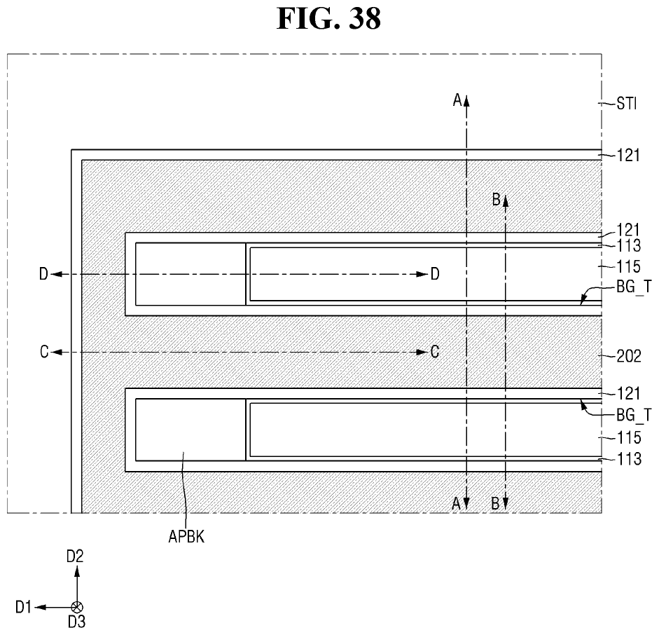

Referring to FIGS. 38 to 40, after forming the back gate capping patterns 115, the upper mask film 12 may be removed.

The back gate capping patterns 115 may have a portion extending upward above the upper side of the lower mask film 11. The active pattern separation structures APBK may have a shape that protrudes upward above the upper side of the lower mask film 11.

A pair of spacer patterns 121 may then be formed on side walls of the back gate insulating pattern 113. The spacer pattern 121 may also be formed on the side walls of the active pattern separation structure APBK.

While the upper mask film 12 is being removed, a part of the cell region element separation film STI may be removed. Therefore, a step structure may be formed along the boundary of the active layer 202 of the cell array region CAR. The spacer pattern 121 may be formed on the step structure of the cell region element separation film STI.

More specifically, the spacer film may be formed along the upper side of the lower mask film 11, the side walls of the back gate insulating patterns 113, and the upper sides of the back gate capping patterns 115. The spacer film may be formed along the side walls of the active pattern separation structure APBK and the upper side of the active pattern separation structure APBK. The spacer film may be formed at a uniform thickness. The spacer pattern 121 may be formed by performing an anisotropic etching process on the spacer film. The active layer 202 may be exposed while the spacer pattern 121 is being formed.

The widths of the active patterns of the vertical channel transistors may be determined based on a deposited thickness of the spacer film. The spacer film may be made up of an insulating material. The spacer film may include, for example, silicon oxide, silicon oxynitride, silicon nitride, silicon carbide (SiC), silicon carbon nitride film (SiCN), combinations thereof, and the like.

Referring to FIGS. 38 to 43, an anisotropic etching process may be performed on the active layer 202, using the spacer pattern 121 as an etching mask.

Pre-active patterns PAP that extend along each back gate electrode BG may be formed. As the pre-active patterns PAP are formed, the buried insulating film 201 may be exposed. The pre-active pattern PAP may be formed along the side walls of the active pattern separation structure APBK.

While the pre-active pattern PAP is being formed, a word line trench WL_T is formed.

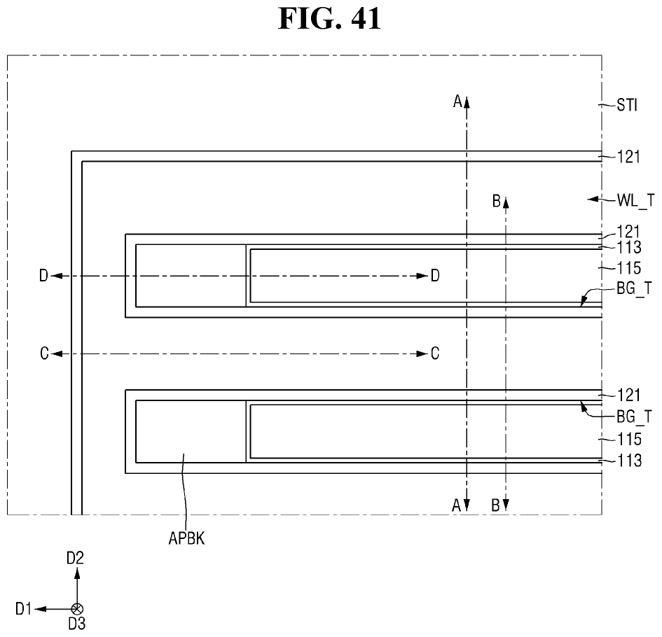

Referring to FIGS. 41 to 46, a sacrificial film that fills the word line trench WL_T may be formed.

An active mask pattern may be formed on the sacrificial film. The active mask pattern may have a linear shape extending in the second direction D2. As another example, the active mask pattern may have the linear shape extending in a diagonal direction with respect to the first direction D1 and the second direction D2. The sacrificial film may be etched using the active mask pattern as an etch mask to form sacrificial openings in the sacrificial film.

By etching the pre-active patterns PAP exposed to the sacrificial openings, a first active pattern AP1 and a second active pattern AP2 may be formed on both sides of the back gate electrode BG. The first active patterns AP1 may be formed on the first side walls of the back gate electrode BG to be spaced apart from each other in the first direction D1. The second active patterns AP2 may be formed on the second side walls of the back gate electrode BG to be spaced apart from each other in the first direction D1. Since the first active pattern AP1 and the second active pattern AP2 are formed, the sacrificial openings may expose a part of the back gate insulating pattern 113.

In addition, the first dummy active pattern APD1 and the second dummy active pattern APD2 may be formed on both sides of the back gate electrode BG. The first dummy active pattern APD1 may be spaced apart from the first active pattern AP1 in the first direction D1. The second dummy active pattern APD2 may be spaced apart from the second active pattern AP2 in the first direction D1.

Thereafter, the sacrificial film, the active mask pattern, the spacer pattern 121 and the lower mask film 11 may be removed. Accordingly, the first active pattern AP1, the second active pattern AP2, the first dummy active pattern APD1, and the second dummy active pattern APD2 may be exposed. Further, the buried insulating film 201 may be exposed.

In one variation, the first dummy active pattern APD1 and the second dummy active pattern APD2 may not be formed on both sides of the back gate electrode BG.

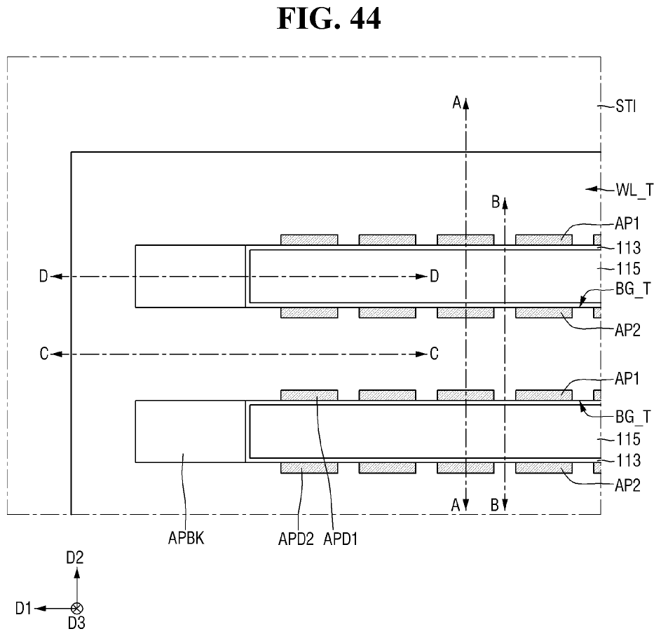

Referring to FIGS. 44 to 47, the gate insulating pattern GOX may be formed along the side walls of the first active pattern AP1, the side walls of the second active pattern AP2, the side walls of the first dummy active pattern APD1, the side walls of the second dummy active pattern APD2, the upper side of the back gate capping pattern 115, and the upper side of the buried insulating layer 201.

The gate insulating pattern GOX may be formed along the side walls of the cell region element separation film STI and the side walls of the active pattern separation structure APBK.

The gate insulating pattern GOX may be formed by, but is not limited to, at least one of physical vapor deposition (PVD), thermal chemical vapor deposition (thermal CVD), low-pressure chemical vapor deposition (LP-CVD), plasma enhanced chemical vapor deposition (PE-CVD) or atomic layer deposition (ALD) techniques.

Subsequently, a first pre-word line WL_P1 may be formed on the gate insulating pattern GOX. The first pre-word line WL_P1 may be formed on the side walls of the first and second active patterns AP1 and AP2. The first pre-word line WL_P1 may be formed on the side wall of the cell region element separation film STI and the side wall of the active pattern separation structure APBK. The first pre-word line WL_P1 extending along the side wall of the cell region element separation film STI may include a first portion extending in the first direction D1 and a second portion extending in the second direction D2.

Formation of the first pre-word line WL_P1 may include a process of performing an anisotropic etching process on the gate conductive film after depositing a gate conductive film on the gate insulating pattern GOX. Here, a deposition thickness of the gate conductive film may be smaller than half a width of the word line trench WL_T.

At the time of the anisotropic etching process on the gate conductive film, the gate insulating pattern GOX may be used as an etching stop film. In one variation, the gate insulating pattern GOX may be over-etched to expose the buried insulating film 201.

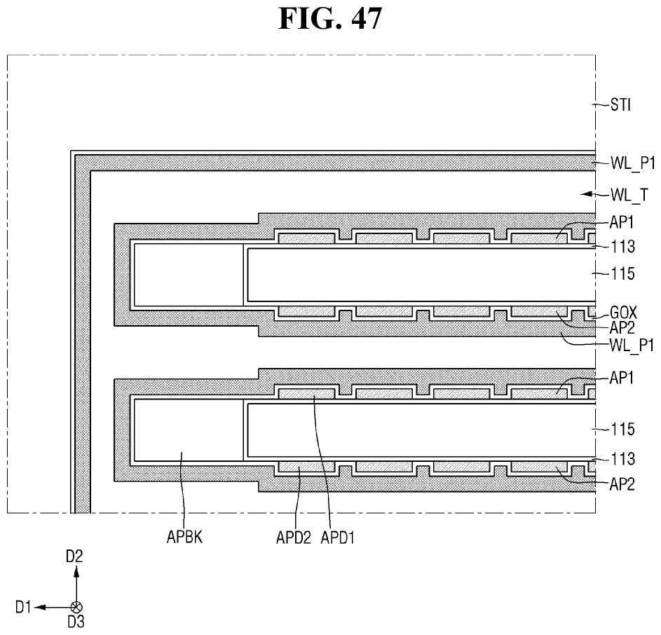

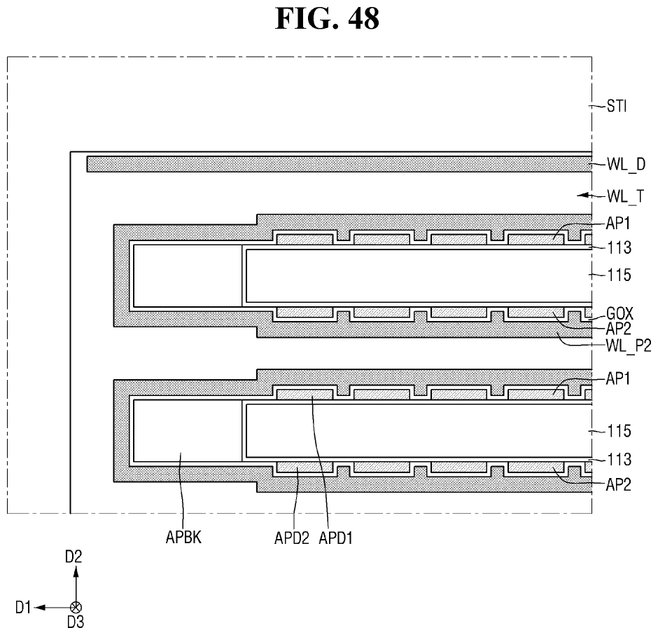

Referring to FIGS. 47 and 48, in the first pre-word line WL_P1 extending along the side wall of the cell region element separation film STI, a second portion extending in the second direction D2 may be removed.

Accordingly, the dummy word line WL_D extending in the first direction D1 along the side wall of the cell region element separation film STI may be formed. Further, the second pre-word line WL_P2 may be formed on the side walls of the first and second active patterns AP1 and AP2 and the side wall of the active pattern separation structure APBK.

The upper side of the dummy word line WL_D and the upper side of the second pre-word line WL_P2 may be located at a level that is lower than the upper sides of the first and second active patterns AP1 and AP2.

As an example, after forming the first and second word lines WL1 and WL2, a gas phase doping (GPD) process or a plasma doping (PLAD) process may be performed. Accordingly, impurities may be doped into the first and second active patterns AP1 and AP2 through the gate insulating patterns GOX exposed by the second pre-word line WL_P2. While the first and second active patterns AP1 and AP2 are doped with impurities, the first and second dummy active patterns APD1 and APD2 may be doped with impurities.

Referring to FIGS. 48 to 51, the gate separation pattern GSS may be formed on the dummy word line WL_D and the second pre-word line WL_P2.

For example, the upper side of the gate separation pattern GSS may be disposed on the same plane as the upper side of the back gate capping pattern 115.

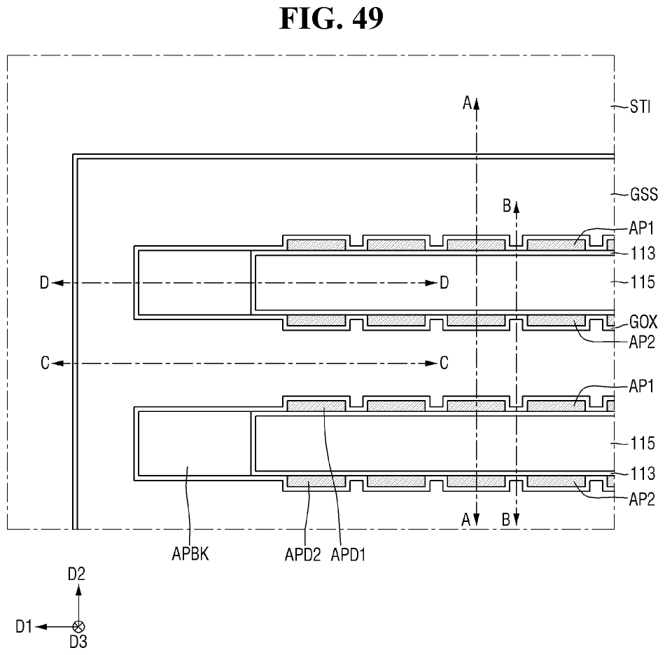

Referring to FIGS. 49 to 54, a word line separation hole WL_CP may be formed in the gate separation pattern GSS. The buried insulating film 201 may be exposed by the word line separation hole WL_CP.

The second pre-word line WL_P2 formed around the back gate electrode BG and the active pattern separation structure APBK may be separated into two portions by the word line separation hole WL_CP. In other words, the second pre-word line WL_P2 may be separated into the first word line WL1 and the second word line WL2 by the word line separation hole WL_CP.

In FIG. 10, a space in which the third connecting extending part WL_CE3 of the first word line WL1 is spaced apart from the electrode extending part WL_LE of the second word line WL2 may be a portion in which the word line separation hole WL_CP is formed.

Although not shown, an insulating pattern which fills or is in the word line separation hole WL_CP may be formed.

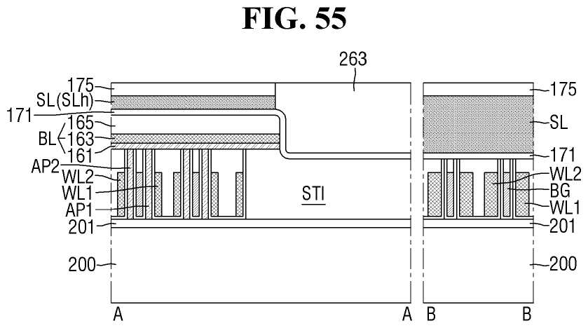

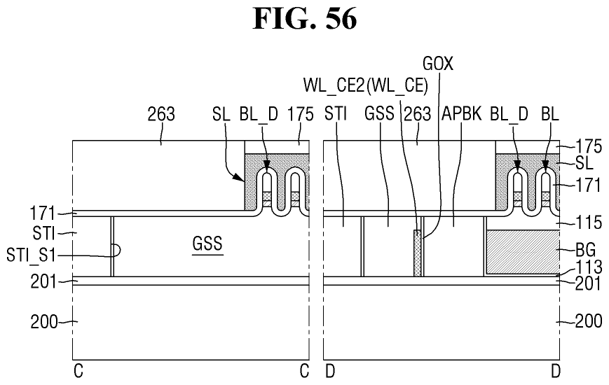

Referring to FIGS. 55 and 56, the bit line BL and the dummy bit line BL_D may be formed on the first and second active patterns AP1 and AP2 and the first and second dummy active patterns (APD1 and APD2 of FIG. 2).

The bit line BL may be formed on the first active pattern AP1 and the second active pattern AP2. The bit line BL may be connected to the first active pattern AP1 and the second active pattern AP2.

The dummy bit line BL_D may be formed on the first dummy active pattern APD1 and the second dummy active pattern APD2.

The shielding insulating liner 171 may then be formed along the profile of the bit line BL and the profile of the dummy bit line BL_D. A shielding conductive pattern SL and a shielding insulating capping film 175 may be formed on the shielding insulating liner 171.

Subsequently, the first upper insulating film 263 may be formed on the shielding insulating liner 171. The first upper insulating film 263 may cover or overlap the side walls of the shielding conductive pattern SL and the side walls of the shielding insulating capping film 175. The upper side of the first upper insulating film 263 may be disposed on the same plane as the upper side of the shielding insulating capping film 175.

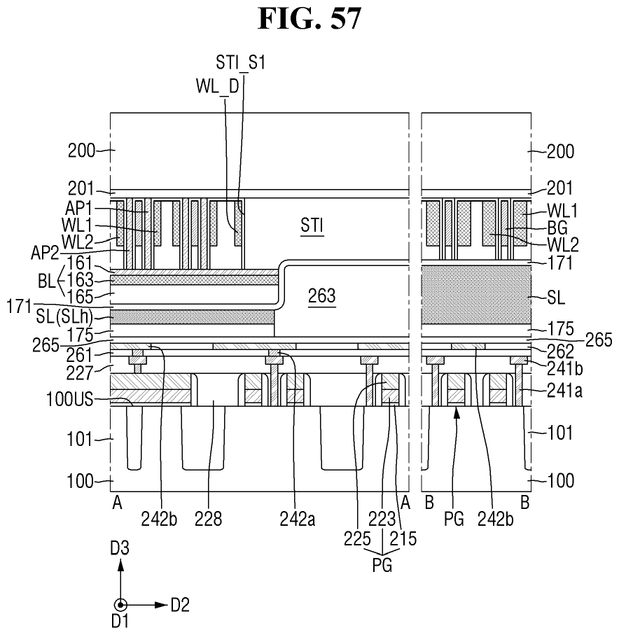

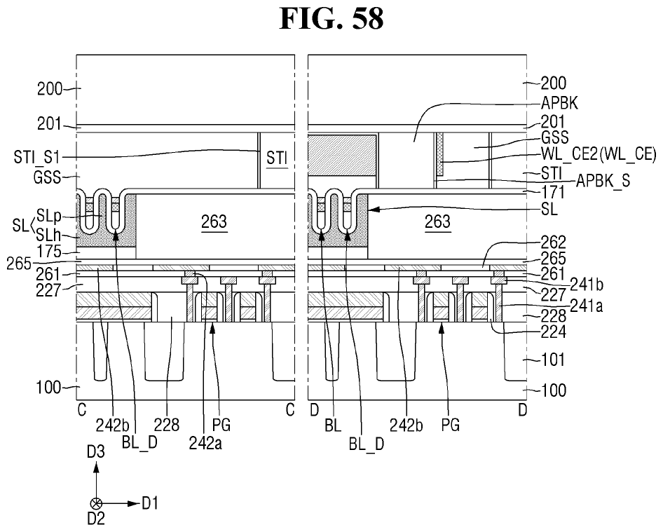

Referring to FIGS. 57 and 58, the sub-substrate 200 formed with back gate electrodes BG, word lines WL1 and WL2, active patterns AP1 and AP2, bit lines BL, and the shielding conductive pattern SL may be bonded to the substrate 100.

In other words, the substrate 100 on which the peri-gate structure PG and the peri-connecting structures 242a and 242b are formed may be bonded to the sub-substrate 200.

Referring to FIGS. 57 to 60, after bonding the sub-substrate 200 and the substrate 100, a back lapping process for removing the sub-substrate 200 may be performed.

Removal of the sub-substrate 200 may include a process of exposing the buried insulating film 201 by sequentially performing a grinding process and a wet etching process.

Next, the buried insulating film 201 may be removed to expose the first active pattern AP1 and the second active pattern AP2. By removing the buried insulating film 201, a part of the gate insulating pattern GOX and a part of the back gate insulating pattern 113 may be exposed.

Next, the exposed gate insulating pattern GOX and the exposed back gate insulating pattern 113 may be removed. The back gate electrode BG, the first word line WL1, and the second word line WL2 may be exposed accordingly.

Thereafter, an etch-back process may be performed to remove a part of the first word line WL1 and a part of the second word line WL2. The gate capping pattern 143 may be formed on the recessed first and second word lines WL1 and WL2.

By performing an etch-back process, a part of the back gate electrode BG may be removed. The back gate separation pattern 111 may be formed on the recessed back gate electrode BG.

A contact hole for exposing the first active pattern AP1 and the second active pattern AP2 may be formed in the contact interlayer insulating film 231.

The contact pattern BC may be formed in the contact hole. The contact patterns BC may be formed on the first active pattern AP1 and the second active pattern AP2. The contact patterns BC may be connected to the first active pattern AP1 and the second active pattern AP2.

Further, a bit line contact plug 281a connected to the bit line BL may be formed. A word line contact plug 281b connected to the word lines WL1 and WL2 may be formed. First and second upper peripheral contact plugs 283a and 283b may be formed. The first and second upper peripheral contact plugs 283a and 283b connected to the peri-connecting wiring 242b may be formed.

Next, a landing pad LP may be formed on the contact pattern BC. The landing pad LP may be formed in the pad separation insulating film 245. The first and second upper connecting wirings 282a and 282b may be formed in the pad separation insulating film 245. The first upper connecting wiring 282a may connect the bit line contact plug 281a and the first upper peripheral contact plug 283a. The second upper connecting wiring 282b may connect the word line contact plug 281b and the second upper peripheral contact plug 283b.

Next, referring to FIGS. 3 and 4, the data storage patterns DSP may be formed on landing pad LP.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor memory device comprising:
a cell region element separation film that is on a substrate and comprises a first cell region side wall and a second cell region side wall, wherein the first cell region side wall extends in a first direction, and wherein the second cell region side wall extends in a second direction;
an active pattern that is on the substrate and comprises a first side wall and a second side wall that are opposite to each other in the first direction and a first side and a second side that are opposite to each other in a third direction, wherein the first side of the active pattern faces the substrate;
a word line that is on the first side wall of the active pattern and extends in the second direction;
a back gate electrode that is on the second side wall of the active pattern and extends in the second direction;
a bit line that is electrically connected to the first side of the active pattern and extends in the first direction; and
a data storage pattern that is electrically connected to the second side of the active pattern,
wherein the word line comprises an electrode part that extends in the second direction and along the back gate electrode,
wherein the word line comprises a plug connecting part that extends beyond the back gate electrode in the second direction,
wherein the plug connecting part of the word line comprises a first connecting extending part that extends in the first direction and a second connecting extending part that extends in the second direction, and
wherein the second connecting extending part of the word line is between the electrode part of the word line and the first connecting extending part of the word line.

2. The semiconductor memory device of claim 1, further comprising a word line contact plug that is electrically connected to the word line, wherein the word line contact plug is electrically connected to the first connecting extending part of the word line.

3. The semiconductor memory device of claim 1, wherein the first connecting extending part of the word line extends from the second side wall of the active pattern and toward the first side wall of the active pattern.

4. The semiconductor memory device of claim 1, wherein the first connecting extending part of the word line extends from the first side wall of the active pattern to the second side wall of the active pattern.

5. The semiconductor memory device of claim 1, wherein the plug connecting part of the word line further comprises a third connecting extending part that is electrically connected to the first connecting extending part of the word line and extends in the second direction and toward the back gate electrode.

6. The semiconductor memory device of claim 1, further comprising an active pattern separation structure, wherein:
a terminal end of the back gate electrode faces the active pattern separation structure, and
the second connecting extending part of the word line extends along a side wall of the active pattern separation structure.

7. The semiconductor memory device of claim 6, wherein the first connecting extending part of the word line extends along the side wall of the active pattern separation structure.

8. The semiconductor memory device of claim 6, wherein:
the active pattern separation structure contacts the cell region element separation film, and
the first connecting extending part of the word line is not between the active pattern separation structure and the cell region element separation film.

9. The semiconductor memory device of claim 1, further comprising a dummy boundary word line that extends along the second side wall of the cell region element separation film.

10. The semiconductor memory device of claim 9, wherein the dummy boundary word line does not extend along the first side wall of the cell region element separation film.

11. The semiconductor memory device of claim 1, further comprising a shielding conductive pattern disposed on the substrate, wherein:
the shielding conductive pattern comprises a shielding conductive plate and a plurality of shielding conductive protruding patterns that extend from the shielding conductive plate in the first direction, and
the bit line is between two adjacent shielding conductive protruding patterns of the plurality of shielding conductive protruding patterns.

12. A semiconductor memory device comprising:
a cell region element separation film that is on a substrate and comprises a first cell region side wall and a second cell region side wall, wherein the first cell region side wall extends in a first direction, and wherein the second cell region side wall extends in a second direction;
back gate electrodes that are on the substrate and extend in the second direction;
a first word line and a second word line that are between the back gate electrodes and extend in the second direction;
active patterns that are between the second word line and the first word line and that are spaced apart in the second direction;
bit lines that are between the substrate and the first and second word lines and that extend in the first direction; and
a data storage pattern that is on and electrically connected to the active patterns,
wherein each of the first word line and the second word line comprises an electrode part that extends in the second direction and along the back gate electrodes and a plug connecting part that extends from the back gate electrodes and in the second direction,
wherein each of the plug connecting part of the first word line and the plug connecting part of the second word line comprises a first connecting extending part that extends in the first direction and a second connecting extending part that extends in the second direction,
wherein the second connecting extending part of the first word line is between the electrode part of the first word line and the first connecting extending part of the first word line, and
wherein the second connecting extending part of the second word line is between the electrode part of the second word line and the first connecting extending part of the second word line.

13. The semiconductor memory device of claim 12, wherein:
each of the first word line and the second word line further comprises an electrode extending part that extends beyond the back gate electrodes in the second direction,
the electrode part of the first word line is between the plug connecting part of the first word line and the electrode extending part of the first word line,
the electrode part of the second word line is between the plug connecting part of the second word line and the electrode extending part of the second word line, and
the plug connecting part of the first word line overlaps the plug connecting part of the second word line in the first direction.

14. The semiconductor memory device of claim 13, wherein:
the active patterns comprise first active patterns and second active patterns,
wherein the back gate electrodes comprise a first back gate electrode and a second back gate electrode that are adjacent to each other in the first direction,
the first active patterns are between the first back gate electrode and the first word line,
the second active patterns are between the second back gate electrode and the second word line,
the first connecting extending part of the first word line overlaps the first back gate electrodes in the second direction, and
the first connecting extending part of the second word line overlaps the second back gate electrode in the second direction.

15. The semiconductor memory device of claim 12, wherein:
each of the first word line and the second word line further comprises an electrode extending part that extends beyond the back gate electrodes in the second direction,
the electrode part of the first word line is between the plug connecting part of the first word line and the electrode extending part of the first word line,
the electrode part of the second word line is between the plug connecting part of the second word line and the electrode extending part of the second word line,
the plug connecting part of the first word line overlaps the electrode extending part of the second word line in the first direction, and
the plug connecting part of the second word line overlaps the electrode extending part of the first word line in the first direction.

16. The semiconductor memory device of claim 15, wherein:
the active patterns comprise first active patterns and second active patterns,
the back gate electrodes comprise a first back gate electrode and a second back gate electrode that are adjacent to each other in the first direction,
the first active patterns are between the first back gate electrode and the first word line,
the second active patterns are between the second back gate electrode and the second word line,
the first connecting extending part of the first word line overlaps the first back gate electrode in the second direction, and
the first connecting extending part of the second word line overlaps the second back gate electrode in the second direction.

17. The semiconductor memory device of claim 15, wherein:
the active patterns comprise first active patterns and second active patterns,
the back gate electrodes comprise a first back gate electrode and a second back gate electrode that are adjacent to each other in the first direction,
the first active patterns are between the first back gate electrode and the first word line,
the second active patterns are between the second back gate electrode and the second word line,
the first connecting extending part of the first word line does not overlap the first back gate electrode in the second direction, and
the first connecting extending part of the second word line does not overlap the second back gate electrode in the second direction.

18. The semiconductor memory device of claim 12, further comprising:
a first word line contact plug electrically connected to the first connecting extending part of the first word line, and
a second word line contact plug electrically connected to the first connecting extending part of the second word line.

19. A semiconductor memory device comprising:
a peri-gate structure on a substrate;
a shielding conductive pattern that is on the peri-gate structure and comprises a shielding conductive plate and a plurality of shielding conductive protruding parts that extend from the shielding conductive plate in a first direction;
bit lines that are on the shielding conductive pattern and extend in the first direction;
a cell region element separation film that is on the peri-gate structure;
back gate electrodes that are on the bit lines and extend in a second direction, wherein the back gate electrodes comprise a first back gate electrode and a second back gate electrode;
active pattern separation structures on opposing sides of the back gate electrode;
a first word line and a second word line that are on the bit line, between the back gate electrodes, between the active pattern separation structures, and extend in the second direction;
a first word line contact plug electrically connected to the first word line;
a second word line contact plug electrically connected to the second word line;
first active patterns that are between the first back gate electrode and the first word line, electrically connected to the bit line, and spaced apart in the second direction;
second active patterns that are between the second back gate electrode and the second word line, electrically connected to the bit line, and spaced apart in the second direction; and
a data storage pattern that is on and electrically connected to the first active pattern and the second active pattern,
wherein each of the first word line and the second word line comprises a plug connecting part that extends beyond the back gate electrodes in the second direction,
wherein each of the plug connecting part of the first word line and the plug connecting part of the second word line comprises a first connecting extending part that extends in the second direction along a side wall of the active pattern separation structure, a second connecting extending part that is electrically connected to the first connecting extending part and that extends in the first direction, and a third connecting extending part that is electrically connected to the second connecting extending part and that extends in the second direction,
wherein the first word line contact plug is electrically connected to the second connecting extending part of the first word line, and
wherein the second word line contact plug is electrically connected to the second connecting extending part of the second word line.

20. The semiconductor memory device of claim 19, wherein:
the active pattern separation structures contact the cell region element separation film, and
the second connecting extending part of the first word line and the second connecting extending part of the second word line are not between the active pattern separation structures and the cell region element separation film.
